(19) United States
(12) Patent Application Publication
(10) Pub. No.: US 2015/0041993 A1
(43) Pub. Date: Feb. 12, 2015

(54) METHOD FOR MANUFACTURING A CHIP ARRANGEMENT, AND A CHIP ARRANGEMENT

(71) Applicant: Infineon Technologies AG, Neubiberg (DE)

(72) Inventor: Petteri Palm, Regensburg (DE)

(73) Assignee: Infineon Technologies AG, Neubiberg (DE)

(21) Appl. No.: 13/959,795

(22) Filed: Aug. 6, 2013

(51) Int. Cl. H01L 23/58; H01L 23/31; H01L 21/56

(52) U.S. Cl. CPC H01L 23/585; H01L 21/561; H01L 23/31
USPC 257/782; 438/127; 438/119; 257/787

(57) ABSTRACT

A method for manufacturing a chip arrangement may include: disposing a stabilizing structure and a chip including at least one contact next to each other and over a carrier; encapsulating the chip and the stabilizing structure by means of an encapsulating structure; and forming an electrically conductive connection to the at least one contact of the chip.

### TECHNICAL FIELD

Various embodiments relate to a method for manufacturing a chip arrangement, and a chip arrangement.

### BACKGROUND

Chip arrangements, for example chip packages, may include at least one chip (or die) embedded in a material (e.g. an encapsulant). Electrical and/or thermal and/or mechanical properties of a chip arrangement may depend on a process with which the chip arrangement is manufactured. Some manufacturing processes may adversely affect the electrical and/or thermal and/or mechanical properties of a chip arrangement and/or the at least one chip included in the chip arrangement. New ways of manufacturing chip arrangements may be needed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A to FIG. 1G illustrate a conventional method for manufacturing a chip arrangement.

FIG. 2 shows a method for manufacturing a chip arrangement.

FIG. 3A to FIG. 3K show a process-flow illustrating an example of the method shown in FIG. 2.

FIG. 4A and FIG. 4B show an example of a method for forming a bonding layer and a thru-opening.

FIG. 5A and FIG. 5B show a carrier including at least one opening, which may be filled with material of a bonding layer of a stabilizing structure.

FIG. 6A to FIG. 6I show a process-flow illustrating another example of the method shown in FIG. 2.

FIG. 7A to FIG. 7K show a process-flow illustrating yet another example of the method shown in FIG. 2.

FIG. 8A to FIG. 8K show a process-flow illustrating an example of the method shown in FIG. 2 applied to a manufacture of a three-dimensional chip arrangement.

FIG. 9A to FIG. 9C show flow diagrams illustrating other examples of the method shown in FIG. 2.

FIG. 10 shows a chip arrangement.

### DESCRIPTION

The following detailed description refers to the accompanying drawings that show, by way of illustration, specific details and embodiments in which the invention may be practised. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described for structures or devices, and various embodiments are described for methods. It may be understood that one or more (e.g. all) embodiments described in connection with structures or devices may be equally applicable to the methods, and vice versa.

The word “exemplary” is used herein to mean “serving as an example, instance, or illustration”. Any embodiment or design described herein as “exemplary” is not necessarily to be construed as preferred or advantageous over other embodiments or designs.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

The terms “coupled” and/or “electrically coupled” and/or “connected” and/or “electrically connected”, used herein to describe a feature being connected to at least one other implied feature, are not meant to mean that the feature and the at least one other implied feature must be directly coupled or connected together; intervening features may be provided between the feature and at least one other implied feature.

Directional terminology, such as e.g. “upper”, “lower”, “top”, “bottom”, “left-hand”, “right-hand”, etc., may be used with reference to the orientation of figure(s) being described. Because components of the figure(s) may be positioned in a number of different orientations, the directional terminology is used for purposes of illustration and is in no way limiting. It is to be understood that structural or logical changes may be made without departing from the scope of the invention.

Modem chip (or die) arrangements, e.g. chip (or die) packages, may include at least one chip (or die), which may be embedded in a material (e.g. an encapsulant).

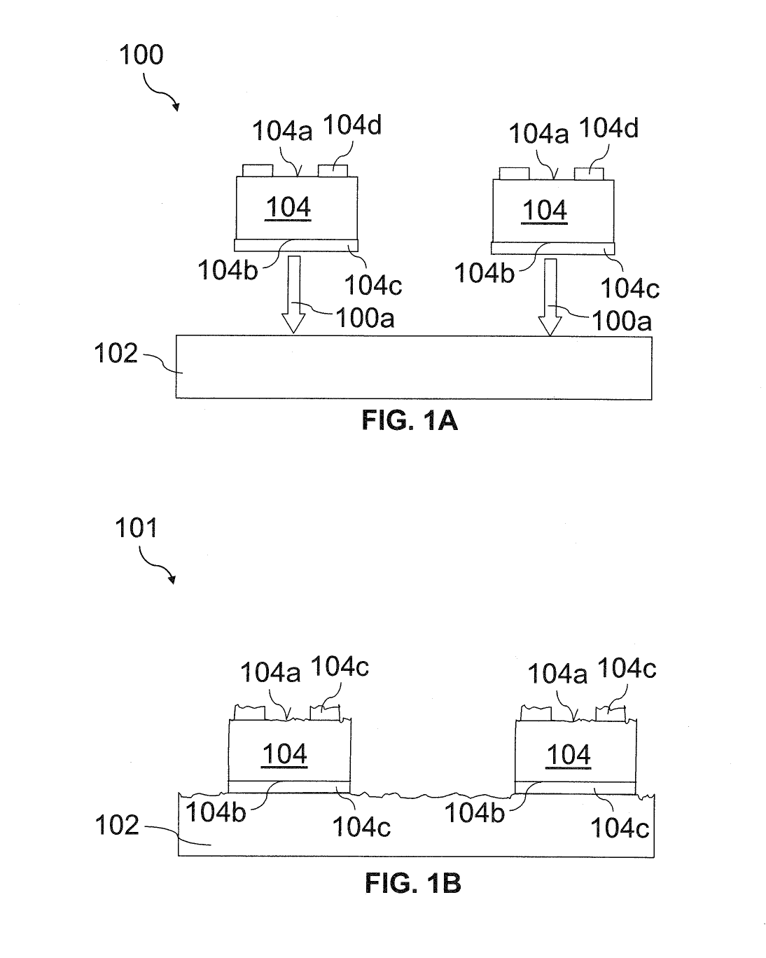

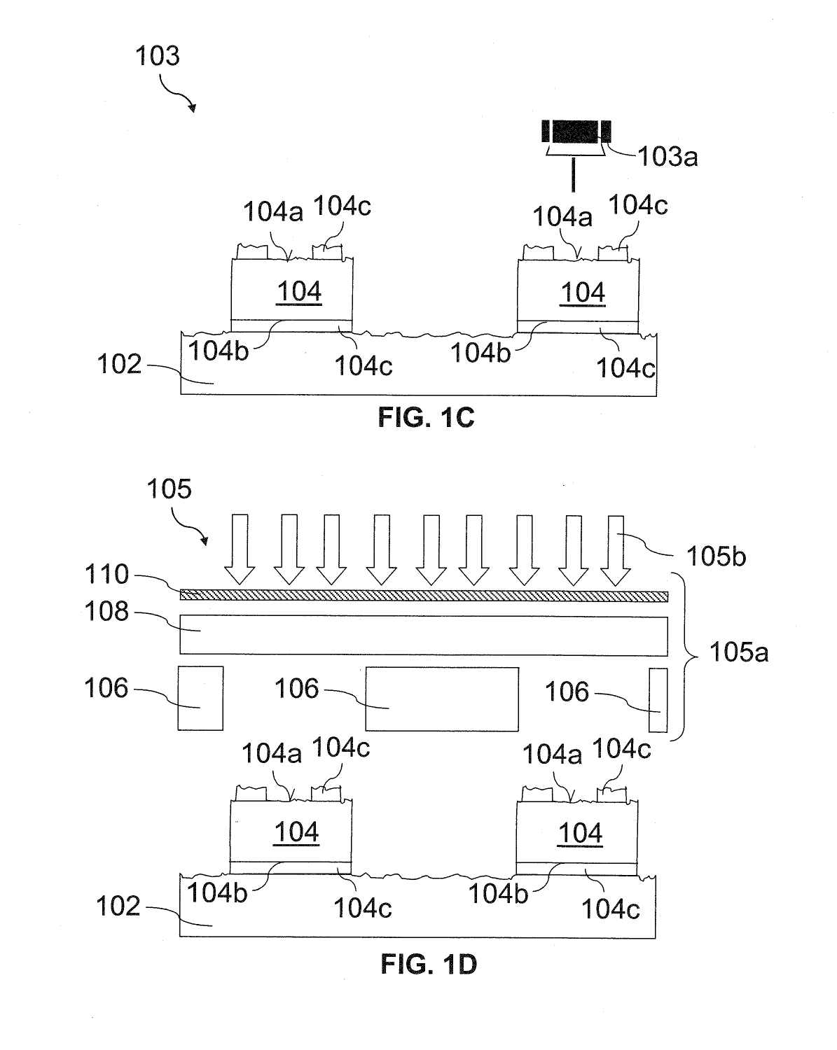

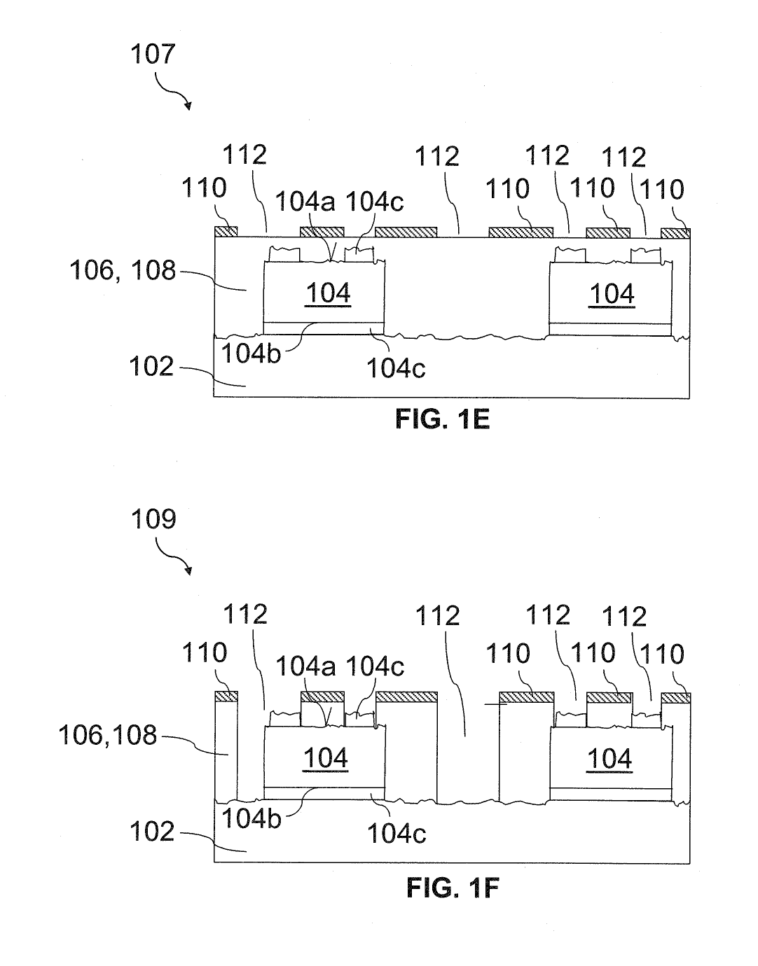

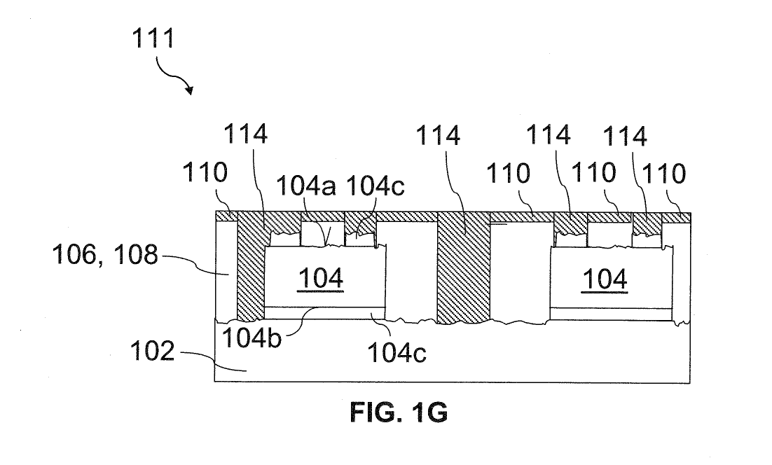

FIG. 1A to FIG. 1G illustrate a conventional method for manufacturing a chip arrangement.

FIG. 1A shows cross-sectional view 100 of a chip arrangement including a leadframe 102 and a chip 104 (or die). The chip 104 (or die) may include a front-side 104a and a back-side 104b. A metallization layer 104c may be formed at the back-side 104b of the chip 104 and at least one contact 104d (e.g. a bonding pad) may be formed at the front-side 104a of the chip 104. The chip 104 may be bonded to the leadframe 102 by means of a bonding process (indicated by arrows 100a), which may be performed at a temperature in the range from about 200° C. to about 350° C.

As shown in FIG. 1B in a view 101, a surface of the leadframe 102 (e.g. copper leadframe) and/or the front-side 104a of the chip 104 may be roughened (e.g. by means of a micro-etching process) in order to, for example, promote adhesion of subsequent layers that may be formed over the chip 104 and/or the leadframe 102.

As shown in FIG. 1C in a view 103, the chip 104 may be inspected (e.g. optically inspected) to determine a relative spatial shift between adjacent chips 104 (or dies) bonded to the leadframe 102. For example, the chip 104 on the left and the chip 104 on the right may be inspected (e.g. optically inspected) by an apparatus 103a, and a relative position between the left chip 104 and the right chip 104 may be determined.

As shown in FIG. 1D in a view 105, a layup 105a may be formed over the chip 104 and the leadframe 102. The layup 105a may include a structured prepreg layer 106, an insulating layer 108 (e.g. a resin and/or an uncured prepreg) and a conductive layer 110. The structured prepreg layer 106 may be disposed over (e.g. disposed directly over) the leadframe 102. The structured prepreg layer 106 may be configured to occupy a gap between adjacent chips 104 bonded to the leadframe 102. For example, as shown in FIG. 1D, the structured prepreg layer 106 may occupy the gap between the chip 104 on the left and the chip 104 on the right. Additionally, the structured prepreg layer 106 may be configured to occupy a gap between a chip 104 and an edge of a leadframe 102, as shown in FIG. 1D. The insulating layer 108 may be disposed over the structured prepreg layer 106, and the conductive layer 110 may be disposed over the insulating layer 108, as shown in FIG. 1D.

Heat and/or pressure (indicated by arrow 105b) may be applied to the layup 105a and the leadframe 102 to bond (e.g. by lamination) the structured prepreg 106, the insulating layer (e.g. a resin) 108 and the conductive layer 110 to the leadframe 102 and the chip 104. Bonding the layup 105a (e.g. by lamination) may be performed over a plurality of leadframes 102 at one time. For example, in BLADE production, eight leadframes 102 may be laminated at one time, and each leadframe may be connected to another leadframe by means of a stencil that may be included in the layup 105a.

As shown in FIG. 1E in a view 107, vias 112 may be formed in the conductive layer 110 (e.g. by means of an etching process).

As shown in FIG. 1F in a view 109, the vias 112 may be extended to expose a part of the leadframe 102 and/or a part of the chip 104. For example, as shown in FIG. 1F, the vias 112 may be extended to expose at least one contact 104c (e.g. a bonding pad) of the chip 104. The vias 112 may be extended by means of a drilling process, for example a laser drilling process.

As shown in FIG. 1G in a view 111, the vias 112 may be filled with a conductive material 114 (e.g. copper or copper alloy or any other suitable metal or metal alloy such as e.g. tungsten). The conductive material 114 may subsequently be structured (e.g. patterned), for example by means of etching.

The conventional method for manufacturing a chip arrangement shown in FIG. 1A to FIG. 1G may suffer from undesirable effects. For example, bonding the chip 104 to the leadframe 102 (e.g. a thick copper layer), for example as shown in FIG. 1A, may be performed at high temperatures (e.g. in the range from about 200° C. to about 350° C.).

High bonding temperatures may cause warpage of the leadframe 102. Whilst it may be noted that a thicker leadframe 102 may reduce warpage caused by the high bonding temperatures, use of a thicker leadframe 102 may lead to a higher bill-of-materials (BOM).

High bonding temperatures may result in a coefficient-of-thermal-expansion (CTE) mismatch between the chip 104 and the leadframe 102. Accordingly, the chip arrangement manufactured using the method shown in FIG. 1A to FIG. 1G may suffer from high residual stress, which may affect the performance of the chip arrangement.

High bonding temperatures may also result in a high risk of failure caused by copper silicides that may be produced during the bonding process.

As described above in relation to FIG. 1D, heat and/or pressure (indicated by arrow 105b) may be applied to the layup 105a and the leadframe 102 to bond (e.g. by lamination) the structured prepreg 106, the insulating layer (e.g. a resin) 108 and the conductive layer 110 to the leadframe 102 and the chip 104. Bonding the layup 105a (e.g. by lamination) may cause at least a part of the layup 105a (e.g. the structured prepreg 106 and/or the insulating layer (e.g. a resin) 108) to shrink. This may lead to warpage of the leadframe 102.

The leadframe 102, upon which the chip 104 is bonded to, may have a small size (e.g. about 165×68 mm²). As described above, a plurality of leadframes 102 may be connected to each other with stencil (e.g. additional PCB stencil) which may be included in the layup 105a. This may lead to a complex layup structure, and a complex leadframe structure. The complex structure may result in poor aligning accuracy between the plurality of leadframes and may suffer from nonlinear dimension changes. For example, small changes in the dimension of a leadframe 102 and/or a chip 104 may lead to disproportionate changes in the dimensions of the stencil and/or layup 105 that may be formed over a plurality of leadframes 102.

FIG. 1A to FIG. 1G illustrate one example of a conventional method for manufacturing a chip arrangement. In another example of a conventional method for manufacturing a chip arrangement, the chip 104 may be bonded to a foil (e.g. a copper foil) by means of a non-conductive adhesive and/or non-conductive paste. In such an example, the front-side 104a of the chip 104 may face the leadframe 102 (which may include, or may be, a foil, e.g. copper foil). In other words, in such an example, a local non-conductive adhesive and/or non-conductive paste may be disposed between the front-side 104a of the chip 104 and the leadframe 102 (e.g. foil, e.g. copper foil). Such a method for manufacturing a chip arrangement may suffer from a high risk of having voids in the non-conductive adhesive and/or non-conductive paste. These voids may consequently lead to yield loss during a patterning process that may be performed, e.g. patterning an electrical connection to and/or at the front-side 104a of the chip 104. Furthermore, the voids may result in delamination of the chip 104 from the leadframe 102 (e.g. foil) and/or HAST (Highly Accelerated Stress Test) problems (e.g. due to trapped plating chemistry). The voids may consequently lead to a loss of reliability of chip arrangements manufactured using such processes that may use a local non-conductive adhesive and/or non-conductive paste disposed between the front-side 104a of the chip 104 and the leadframe 102 (e.g. foil, e.g. copper foil).

In another example of a conventional method for manufacturing a chip arrangement, an eWLB (embedded wafer level ball grid array) process may be used. In such an example, wafer level processes may be used to manufacture the chip arrangement. Furthermore, in an eWLB process, the chip 104 may be disposed (e.g. over a carrier) such that the front-side 104a of the chip 104 may face a carrier during the manufacturing process. In other words, an eWLB process may not have the flexibility of placing the chip 104 in any other orientation (e.g. such that the back-side 104b of the chip 104 may face the carrier).

In view of the above-mentioned features of the conventional method for manufacturing a chip arrangement, a method for manufacturing a chip arrangement is provided. One or more embodiments of the method for manufacturing the chip arrangement may have at least one of the following effects and/or aspects:

An aspect of one or more embodiments may be the use of simple PCB (printed circuit board) manufacturing processes and/or materials to manufacture a chip (or die) arrangement.

An aspect of one or more embodiments may be the use of a panel that may be commonly used as a PCB (printed circuit board) material and/or in a PCB process.

An aspect of one or more embodiments may be replacement of at least a part of a layup (e.g. the layup 105a shown in FIG. 1D) with a stabilizing structure that may not shrink during a lamination process.

An effect of one or more embodiments may be prevention or substantially reduction of warping in at least a part of a leadframe.

An effect of one or more embodiments may be prevention or substantial reduction of the formation of compounds (e.g. copper silicides) that may damage a chip.

An effect of one or more embodiments may be prevention or substantial reduction of CTE mismatch and/or high residual stress.

An effect of one or more embodiments may be manufacture of an interconnection (e.g. metallurgical interconnection) between a chip and a conductive layer in relatively low temperature.

An effect of one or more embodiments may be prevention or substantial reduction of warpage in a conductive layer and/or a chip.

An effect of one or more embodiments may be accurate alignment of a chip on a carrier, which may include, or may be, a panel that may be commonly used as a PCB (printed circuit board) material and/or in a PCB process.

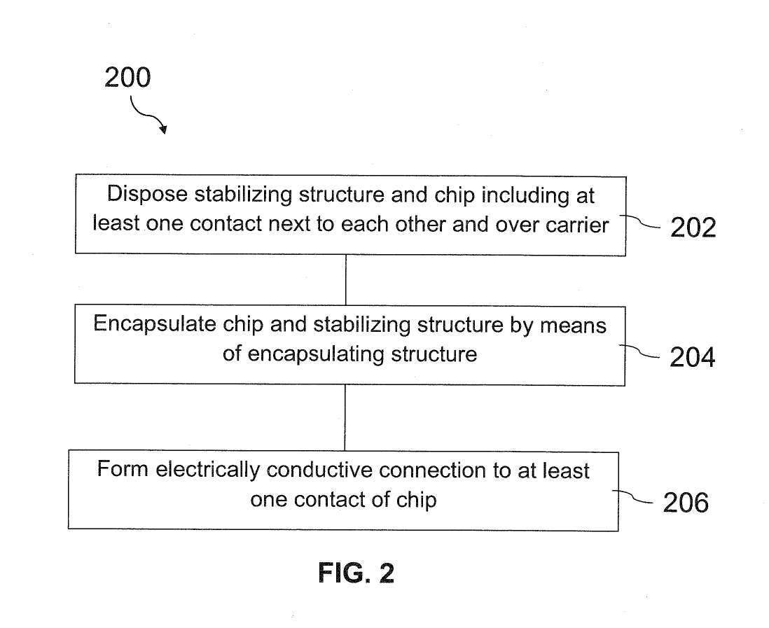

FIG. 2 shows a method 200 for manufacturing a chip arrangement.

The method 200 may, for example, be used to manufacture an embedded chip (or die) arrangement.

The method 200 for manufacturing the chip arrangement may include: disposing a stabilizing structure and a chip including at least one contact next to each other and over a carrier (in 202); encapsulating the chip and the stabilizing structure by means of an encapsulating structure (in 204); and forming an electrically conductive connection to the at least one contact of the chip (in 206).

An effect provided by the method 200 may be prevention or substantially reduction of warping of at least a part of a leadframe.

An effect provided by the method 200 may be prevention or substantial reduction of the formation of compounds (e.g. copper silicides) that may damage a chip.

An effect provided by the method 200 may be prevention or substantial reduction of CTE mismatch and/or high residual stress.

An effect provided by the method 200 may be manufacture of an interconnection (e.g. metallurgical interconnection) between a chip and a conductive layer in relatively low temperature.

An effect provided by the method 200 may be prevention or substantial reduction of warpage in a conductive layer and/or a chip.

An effect provided by the method 200 may be accurate alignment of a chip on a carrier, which may include, or may be, a panel that may be commonly used as a PCB (printed circuit board) material and/or in a PCB process.

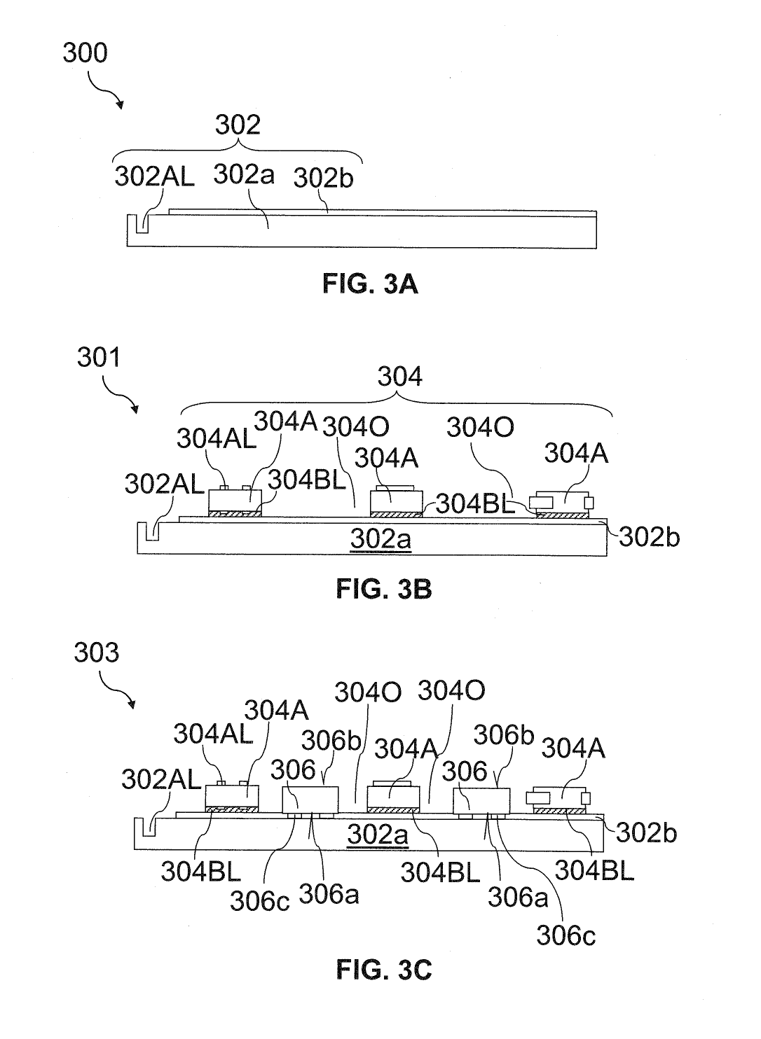

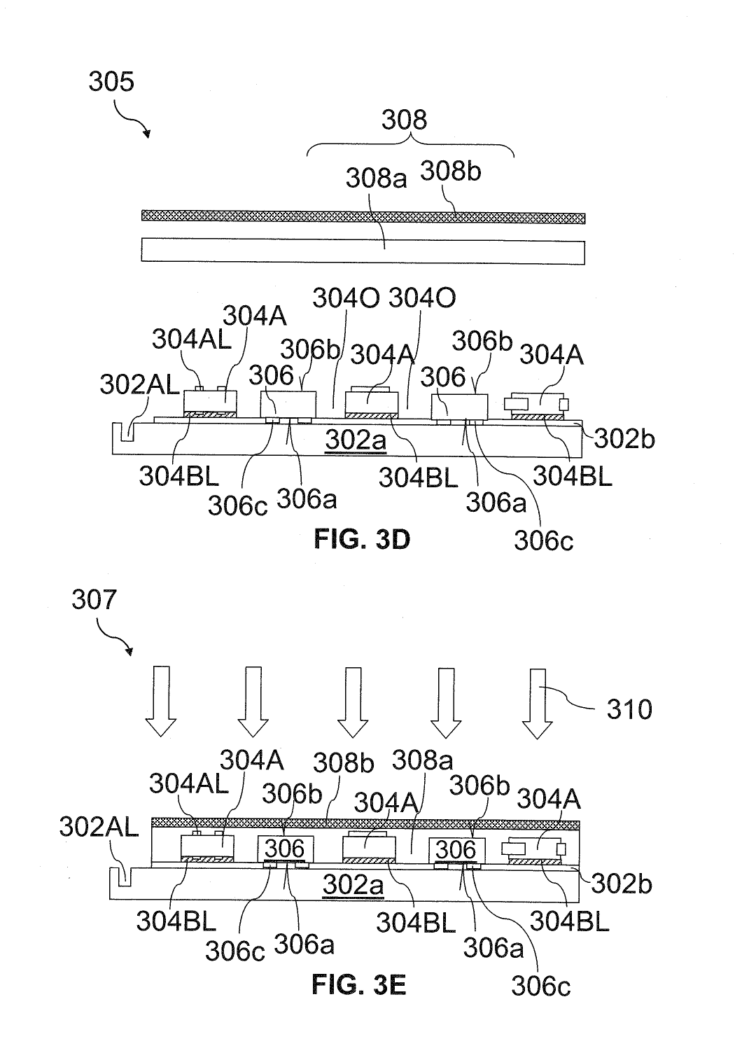

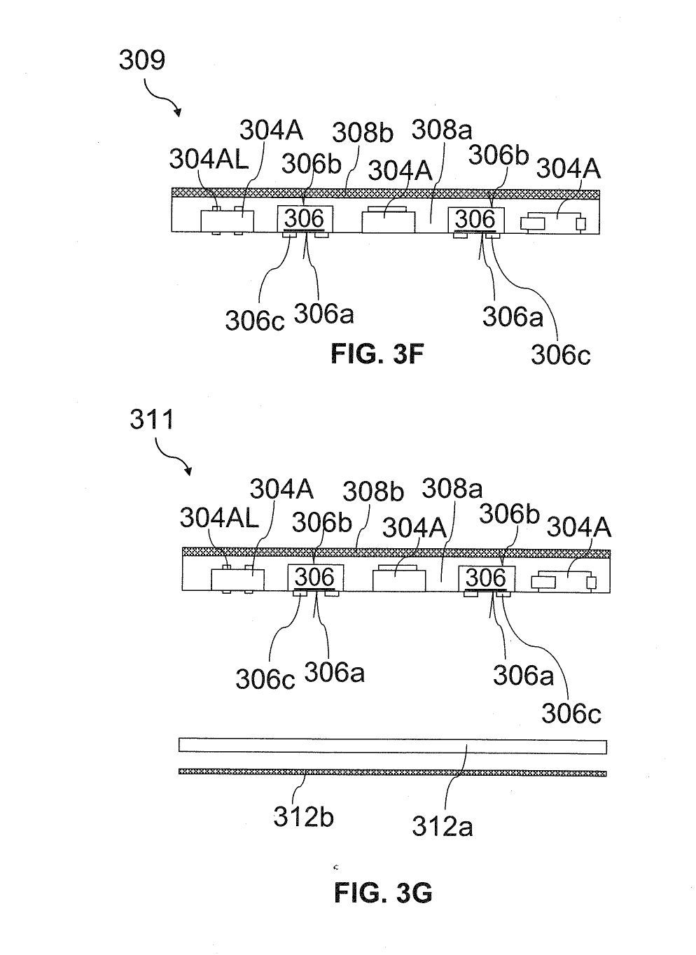

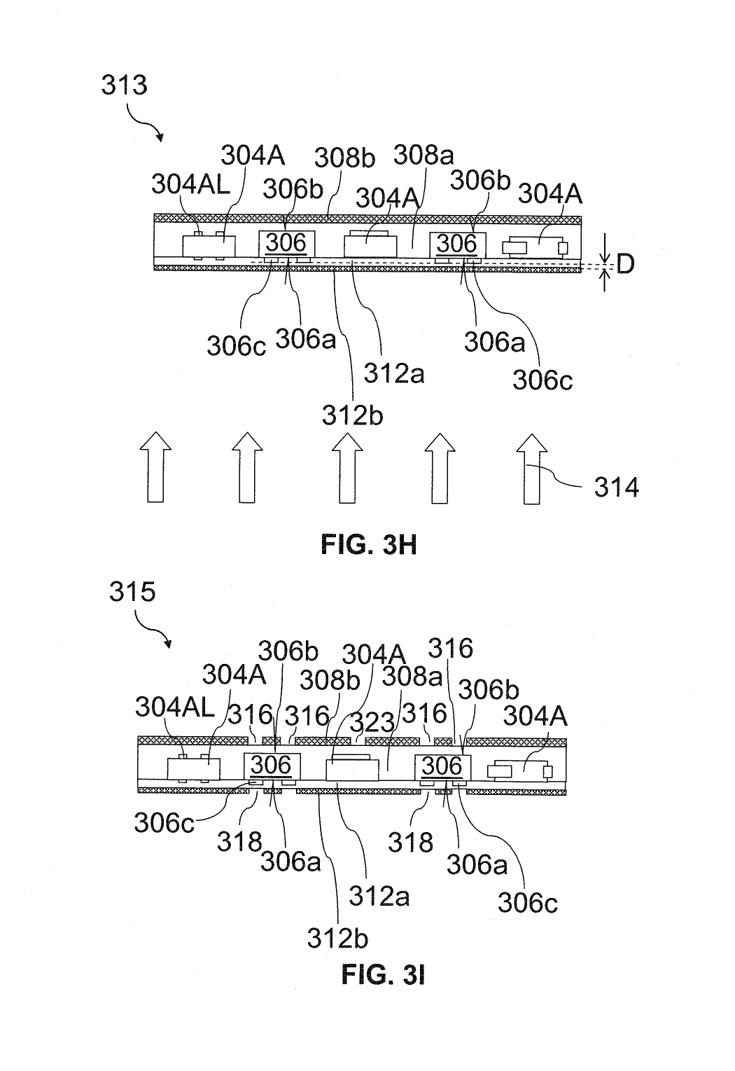

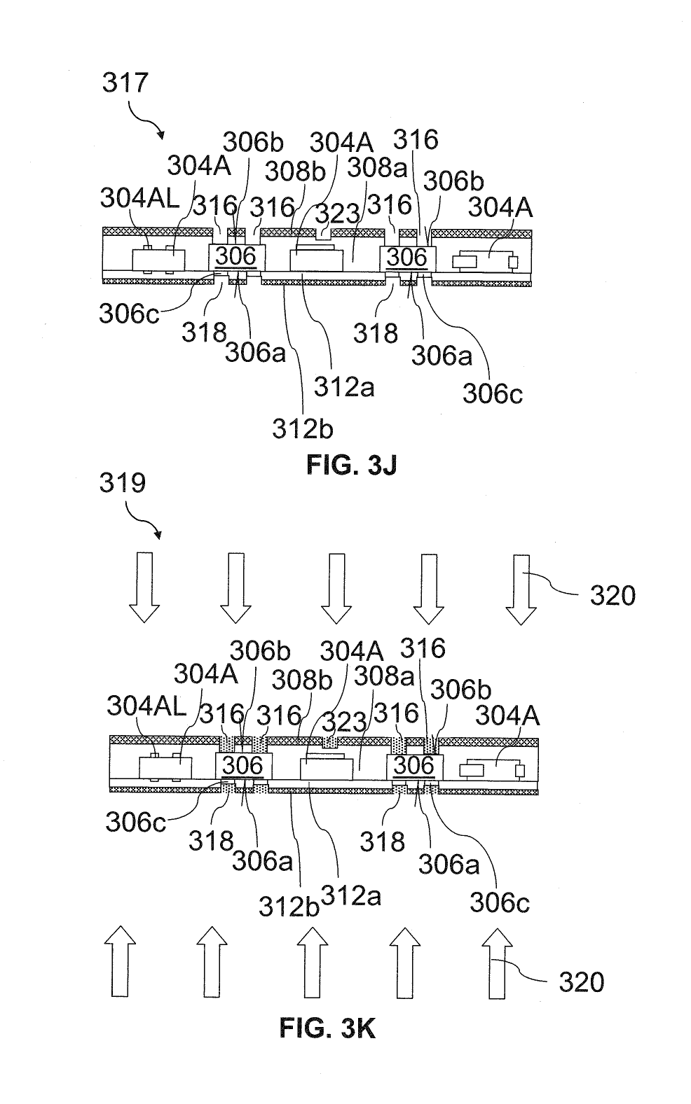

FIG. 3A to FIG. 3K show a process-flow illustrating an example of the method 200 shown in FIG. 2.

FIG. 3A to FIG. 3C show that manufacturing a chip arrangement may include disposing a stabilizing structure 304 and a chip 306 next to each other and over a carrier 302.

In the example shown in FIG. 3A to FIG. 3C, the stabilizing structure 304 may be disposed over the carrier 302 (e.g. as shown in FIG. 3B), and the chip 306 may subsequently be disposed next to the stabilizing structure 304 and over the carrier 302 (e.g. as shown in FIG. 3C). In other words, the stabilizing structure 304 may be disposed over the carrier 302 prior to the chip 306 (e.g. as shown in FIG. 3B and FIG. 3C).

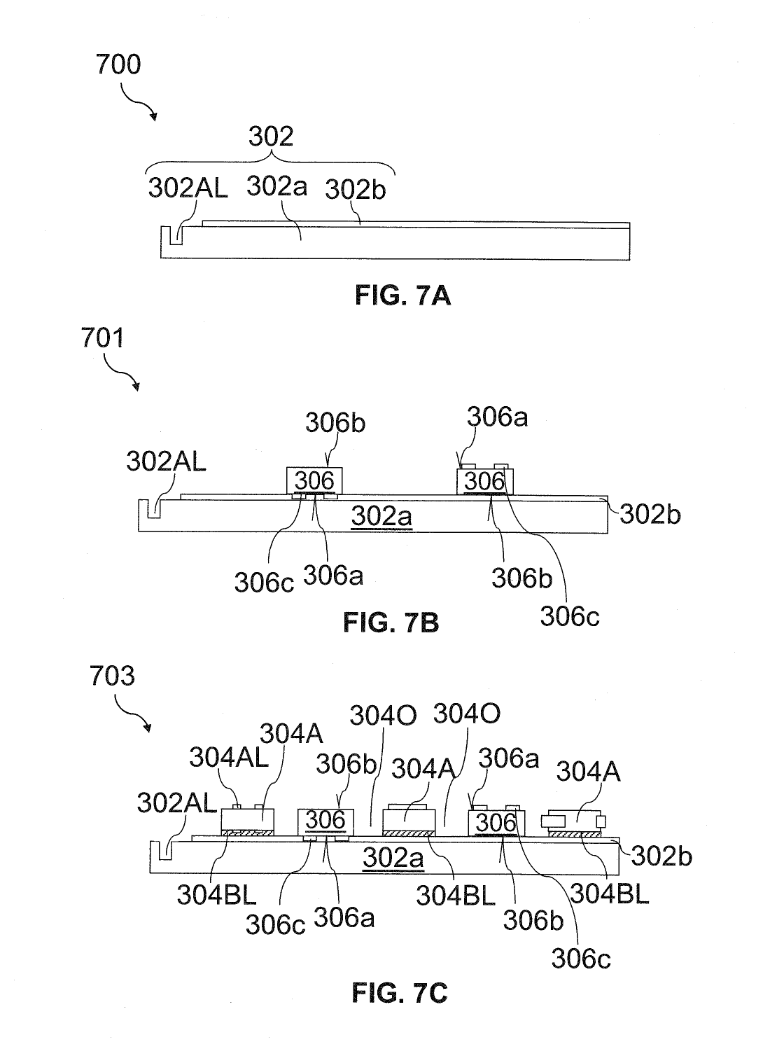

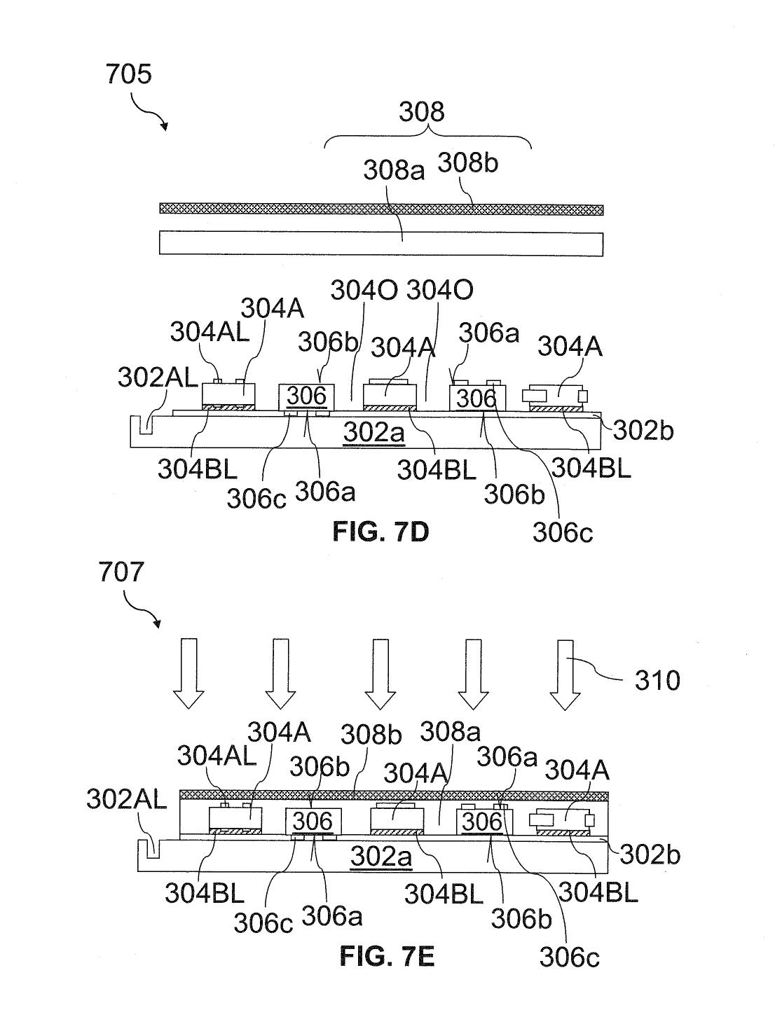

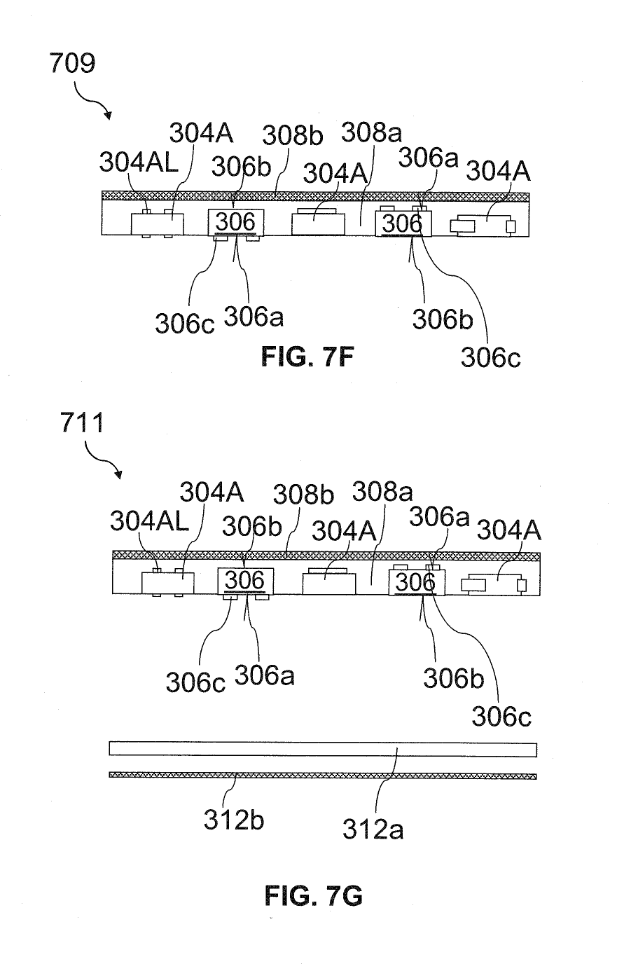

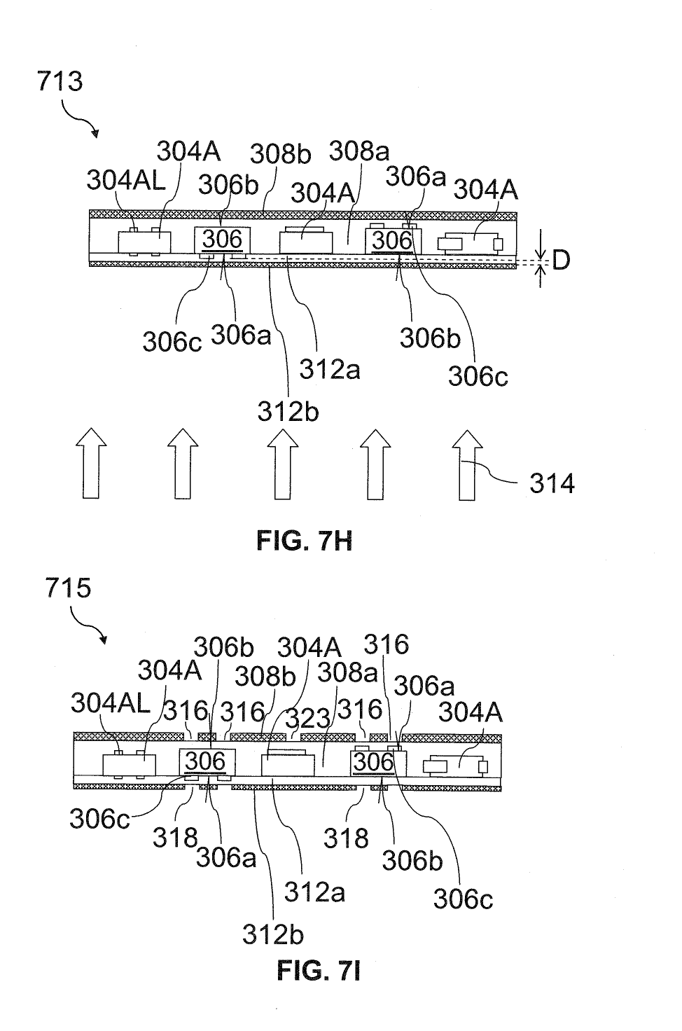

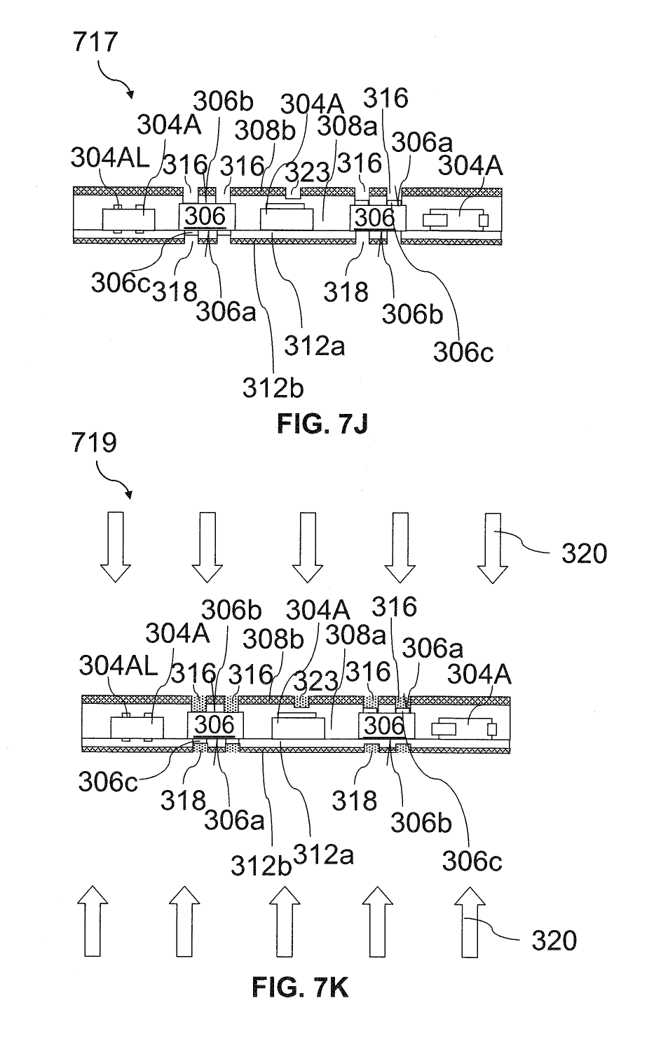

However, in another example, the chip 306 may be disposed over the carrier 302, and the stabilizing structure 304 may subsequently be disposed next to the chip 306 and over the carrier 302. In other words, in another example, the chip 306 may be disposed over the carrier 302 prior to the stabilizing structure 304 (e.g. see description below in respect of FIG. 7B and FIG. 7C).

FIG. 3A shows a cross-sectional view 300 of the carrier 302.

The carrier 302 may include, or may consist of, a plate 302a and an adhesive layer 302b. As shown in FIG. 3A, the adhesive layer 302b may be disposed over (e.g. disposed on) the plate 302a. The adhesive layer 302b of the carrier 302 may, for example, be formed over the plate 302a of the carrier 302 by means of a lamination process (e.g. vacuum lamination process) and/or a deposition process, although other processes may be possible as well.

The carrier 302 (e.g. the plate 302a of the carrier 302) may include, or may be, a panel. The carrier 302 (e.g. the plate 302a of the carrier 302) may include, or may be, a foil (e.g. a conductive foil), e.g. that may be available commercially (e.g. a foil available from Metfoils AB).

The carrier 302 (e.g. the plate 302a of the carrier 302) may include, or may be, a panel measuring about 300×400 mm² that may be commonly used as a PCB (printed circuit board) material. By way of another example, the carrier 302 (e.g. the plate 302a of the carrier 302) may include, or may be, a panel that may have a large panel size (e.g. a panel measuring about 300×400 mm² or larger, for example about 500×600 mm² or larger, although other values may be possible as well).

Since the carrier 302 (e.g. the plate 302a of the carrier 302) may be a large panel (e.g. measuring about 300×400 mm²), the contraction and/or expansion of the carrier 302 may be more predictable over a whole panel area, as compared to, e.g., the leadframe 102 shown in FIG. 1A to FIG. 1G, which may be of a smaller size, e.g. 165×68 mm².

The carrier 302 (e.g. the plate 302a of the carrier 302) may include, or may consist of, a metal or metal alloy. The metal may include at least one metal selected from a group of metals, the group consisting of: aluminium, iron, or an alloy containing at least one of the aforementioned metals, although other metals may be possible as well. For example, the carrier 302 (e.g. the plate 302a of the carrier 302) may include, or may consist of, an alloy including, or consisting of, iron and at least one other element (e.g. carbon). For example, the carrier 302 (e.g. the plate 302a of the carrier 302) may include, or may consist of, steel.

The carrier 302 (e.g. the adhesive layer 302b of the carrier 302) may include, or may consist of, a non-conductive material. The carrier 302 (e.g. the adhesive layer 302b of the carrier 302) may include, or may consist of, a release tape (e.g. a thermal release tape, e.g. a temporary thermal release tape).

The carrier 302 (e.g. the adhesive layer 302b of the carrier 302) may include, or may consist of, a double-sided sticky tape with thermo-release properties (namely, elements and/or components may be separated and/or released from the double-sided sticky tape by means of heating and/or curing the double-sided sticky tape).

The carrier 302 may include at least one alignment mark 302AL, which may be configured to align a structure and/or a component and/or a layer, which may be subsequently formed and/or disposed over the carrier 302.

FIG. 3B shows a cross-sectional view 301 of a stabilizing structure 304 disposed over the carrier 302.

The stabilizing structure 304 may be disposed over the carrier 302 by means of a lamination process (e.g. vacuum lamination process), although other processes may be possible as well. For example, the stabilizing structure 304 may be laminated to the adhesive layer 302b of the carrier 302.

The stabilizing structure 304 may include at least one alignment mark 304AL, which may be configured to align the stabilizing structure 304 to the carrier 302. For example, the at least one alignment mark 304AL of the stabilizing structure 304 may be aligned to the at least one alignment mark 302AL of the carrier 302, thus aligning the stabilizing structure 304 to the carrier 302. In other words, disposing the stabilizing structure 304 over the carrier may include aligning the stabilizing structure 304 to the carrier 302, e.g. by means of the at least one alignment mark 304AL of the stabilizing structure 304 and the at least one alignment mark 302AL of the carrier 302.

The stabilizing structure 304 may include a thru-opening 304O (e.g. one or more thru-openings), which may be formed by means of at least one of a punching process, a routing process, a drilling process, an etching process (e.g. a wet and/or dry etch process), and a laser structuring process, although other processes may be possible as well. The thru-opening 304O may be formed prior to disposing the stabilizing structure 304 over the carrier 302.

The stabilizing structure 304 may include a substrate layer 304A and a bonding layer 304BL disposed over the substrate layer 304A. The bonding layer 304BL may be formed over the substrate layer 304A by means of a lamination process (e.g. vacuum lamination process), although other processes may be possible as well. The bonding layer 304BL may be formed over the substrate layer 304A prior to disposing the stabilizing structure 304 over the carrier 302.

The bonding layer 304BL of the stabilizing structure 304 may be configured to attach the substrate layer 304A of the stabilizing structure 304 to the carrier 302. In this regard, disposing the stabilizing structure 304 over the carrier 302 may include attaching the substrate layer 304A of the stabilizing structure 304 to the carrier 302 (e.g. the adhesive layer 302b of the carrier 302) by means of the bonding layer 304BL of the stabilizing structure 304, as shown in FIG. 3B. For example, the bonding layer 304BL of the stabilizing structure 304 may be disposed between the substrate layer 304A of the stabilizing structure 304 and the carrier 302 (e.g. the adhesive layer 302b of the carrier 302), as shown in FIG. 3B.

The bonding layer 304BL may include, or may be, a resin film (e.g. a B-stage resin film). By way of another example, the bonding layer 304BL may include, or may consist of, a material that may be used for laminating PCB layers together, although other materials may be possible as well.

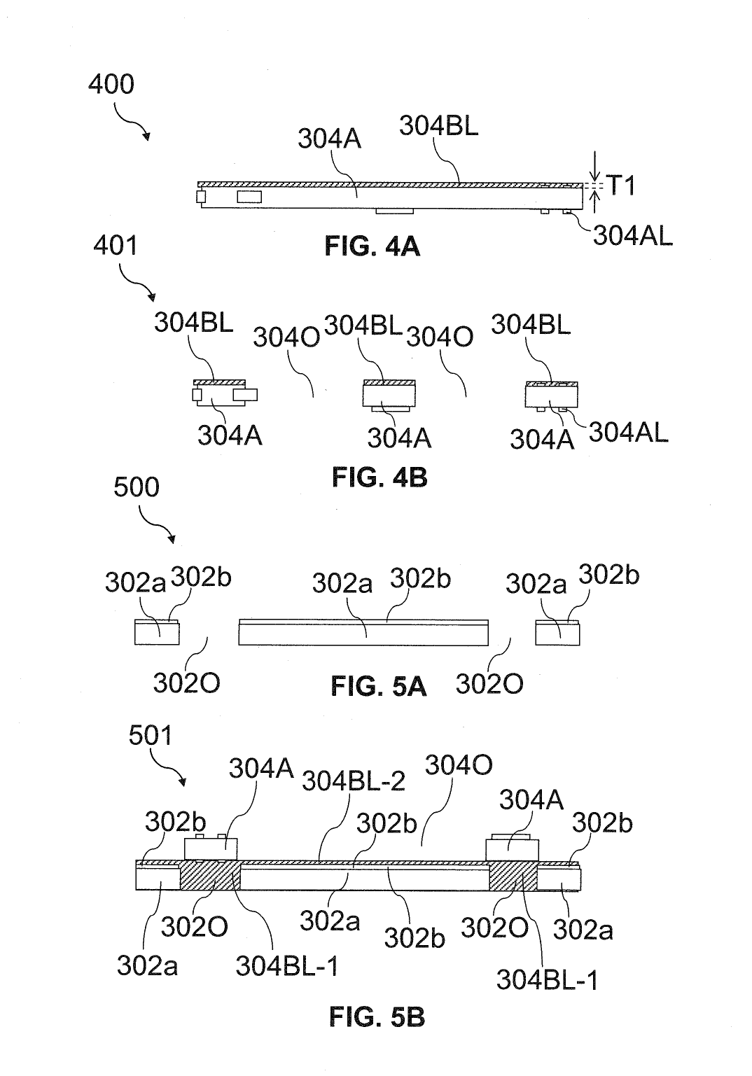

FIG. 4A and FIG. 4B show an example of a method for forming the bonding layer 304BL and the thru-opening 304O of the stabilizing structure 304 prior to disposing the stabilizing structure 304 over the carrier 302.

As shown in FIG. 4A in a view 400, the bonding layer 304BL may be disposed over the substrate layer 304A. As described above, the bonding layer 304BL may be formed over the substrate layer 304A by means of a lamination process.

A thickness T1 of the bonding layer 304BL may depend on a material of the bonding layer 304BL. The thickness T1 of the bonding layer 304BL may be in the range from about 5 μm to about 150 μm, e.g. in the range from about 10 μm to about 100 μm, e.g. in the range from about 20 μm to about 90 μm, e.g. in the range from about 20 μm to about 60 μm, e.g. in the range from about 20 μm to about 40 μm, e.g. about 30 μm.

As shown in FIG. 4B in a view 401, the thru-opening 304O (e.g. at least one thru-opening) may be formed (e.g. through the substrate layer 304A and the bonding layer 304BL) subsequent to forming the bonding layer 304BL over the substrate layer 304A. As described above, the thru-opening 304O may be formed by means of at least one of a punching process, a routing process, a drilling process, an etching process (e.g. a wet and/or dry etch process), and a laser structuring process, although other processes may be possible as well.

The thickness T1 of the bonding layer 304BL may be determined such that there may be at least enough material of the bonding layer 304BL that may fill an opening (e.g. a cavity) of the carrier 302, in case the carrier 302 includes an opening (e.g. cavity). This is illustrated by way of an example in FIG. 5A and FIG. 5B.

FIG. 5A and FIG. 5B show the carrier 302 including at least one opening 302O, which may be filled with material of the bonding layer 304BL of the stabilizing structure 304.

As shown in FIG. 5A in a view 500, the carrier 302 (e.g. the plate 302a of the carrier 302) may include at least one opening 302O. FIG. 5A may, for example, be a magnified view of a portion of the carrier 302 shown in FIG. 3A.

As shown in FIG. 5B in a view 501, the at least one opening 302O of the carrier 302 may be filled with the bonding layer 304BL of the stabilizing structure 304. FIG. 5B may, for example, be a magnified view of a portion of the carrier 302 and the bonding layer 304BL of the stabilizing structure 304 shown in FIG. 3B.

As shown in FIG. 5B, a first portion 304BL-1 of the bonding layer 304BL may fill the at least one opening 302O of the carrier 302, and a second portion 304BL-2 of the bonding layer 304BL may be disposed over at least a part of a surface of the carrier 302 outside the at least one opening 302O. Accordingly, the thickness T1 of the bonding layer 304BL may be determined such that there may be enough material to fill the at least one opening 302O of the carrier and to line (e.g. coat) the part of the surface of the carrier 302 outside the at least one opening 302O, as shown in FIG. 5B.

Accordingly, by determining the thickness T1 of the bonding layer 304BL, the at least one opening 302O of the carrier 302 may be filled with material of the bonding layer 304BL, without having to depend on material of a subsequent layer and/or structure (e.g. an encapsulating structure) to fill the at least one opening 302O of the carrier 302. Consequently, material of a subsequent layer and/or structure (e.g. encapsulating structure) may only need to fill at least a part of the thru-opening 304O of the stabilizing structure 304, without having to fill the at least one opening 302O of the carrier 302.

In relation to FIG. 3B, disposing the stabilizing structure 304 over the carrier 302 may include disposing the stabilizing structure over the at least one opening 302O of the carrier 302, wherein the first portion 304BL-1 of the bonding layer 304BL may fill the at least one opening 302O of the carrier 302, and wherein the a second portion 304BL-2 of the bonding layer 304BL may be disposed over at least a part of the surface of the carrier 302 outside the at least one opening 302O.

The stabilizing structure 304 (e.g. the substrate layer 304A of the stabilizing structure 304) may be configured to prevent or substantially reduce warpage in a chip arrangement manufactured by means of the method 200.

The stabilizing structure 304 (e.g. the substrate layer 304A of the stabilizing structure 304) may be configured to prevent or substantially reduce CTE mismatch and/or high residual stress in a chip arrangement manufactured by means of the method 200.

The stabilizing structure 304 (e.g. the substrate layer 304A of the stabilizing structure 304) may be configured to prevent or substantially reduce shrinkage in a chip arrangement manufactured by means of the method 200.

The stabilizing structure 304 (e.g. the substrate layer 304A of the stabilizing structure 304) may be configured to improve (e.g. optimize) mechanical and/or thermal and/or electrical properties of a chip arrangement manufactured by means of the method 200.

The stabilizing structure 304 (e.g. the substrate layer 304A of the stabilizing structure 304) may be configured to electrically and/or thermally isolate a chip that may be included in a chip arrangement manufactured by means of the method 200.

The stabilizing structure 304 (e.g. the substrate layer 304A of the stabilizing structure 304) may be configured to cool a chip that may be included in a chip arrangement manufactured by means of the method 200.

The stabilizing structure 304 (e.g. the substrate layer 304A of the stabilizing structure 304) may include, or may consist of, a laminate material (e.g. a cured laminate material). For example, the stabilizing structure 304 (e.g. the substrate layer 304A of the stabilizing structure 304) may include, or may consist of, a PCB laminate material (e.g. a cured PCB laminate material). By way of another example, the stabilizing structure 304 (e.g. the substrate layer 304A of the stabilizing structure 304) may include, or may consist of, an FR4 laminate material (e.g. a cured FR4 laminate material).

The stabilizing structure 304 including, or consisting of, the laminate material may, for example, be configured to prevent or substantially reduce warpage and/or CTE mismatch and/or high residual stress and/or shrinkage in a chip arrangement manufactured by means of the method 200. The stabilizing structure 304 including, or consisting of, the laminate material may, for example, be configured to improve (e.g. optimize) mechanical properties of a chip arrangement manufactured by means of the method 200.

The stabilizing structure 304 may include at least one chip (or die) that may, for example, be embedded in the substrate layer 304A of the stabilizing structure 304. The at least one chip (or die) may, for example, be configured to operate in conjunction with a chip, which may be included in the stabilizing structure 304 (e.g. embedded in the substrate layer 304A of the stabilizing structure) and/or which may be external to the stabilizing structure 304. The stabilizing structure 304 including the at least one chip (or die) may, for example, be configured to improve (e.g. optimize) electrical properties of a chip arrangement manufactured by means of the method 200.

The stabilizing structure 304 may include at least one via (e.g. a through-via, e.g. a matrix of through-vias) that may, for example, be embedded in the substrate layer 304A of the stabilizing structure 304. The stabilizing structure 304 including the at least one via (e.g. a matrix of through-vias) may, for example, be configured to improve (e.g. optimize) mechanical and/or thermal and/or electrical properties of a chip arrangement manufactured by means of method 200.

The stabilizing structure 304 (e.g. the substrate layer 304A of the stabilizing structure 304) may include at least one electrically conductive layer (e.g. a copper layer), which may be suitable for routing and/or redistribution of electrical signals.

In an example where the stabilizing structure 304 (e.g. the substrate layer 304A of the stabilizing structure 304) may include one electrically conductive layer, the stabilizing structure 304 (e.g. the substrate layer 304A of the stabilizing structure 304) may include, or may be, a single layer RDL (redistribution layer).

In another example where the stabilizing structure 304 (e.g. the substrate layer 304A of the stabilizing structure 304) may include a plurality of electrically conductive layers, the stabilizing structure 304 may include, or may be, a multi-layer RDL. In such an example, the stabilizing structure 304 (e.g. the substrate layer 304A of the stabilizing structure 304) may include at least one via extending through at least a portion of the stabilizing structure 304 (e.g. the substrate layer 304A of the stabilizing structure 304). The at least one via may, for example, electrically connect a first electrically conductive layer of the plurality of electrically conductive layers to a second electrically conductive layer of the plurality of electrically conductive layers. In other words, at least two electrically conductive layers of the plurality of electrically conductive layers may be electrically connected to each other.

The stabilizing structure 304 (e.g. the substrate layer 304A of the stabilizing structure 304) may include, or may consist of, a polymer material (e.g. a polyimide material). The stabilizing structure 304 including, or consisting of, the polymer material may, for example, be configured to improve (e.g. optimize) mechanical and/or thermal and/or electrical properties of a chip arrangement manufactured by means of the method 200. The stabilizing structure 304 including, or consisting of, the polymer material may, for example, be configured to electrically and/or thermally isolate a chip that may be included in a chip arrangement manufactured by means of method 200.

The stabilizing structure 304 (e.g. the substrate layer 304A of the stabilizing structure 304) may include, or may consist of, a metal or metal alloy. The metal may include at least one metal selected from a group of metals, the group consisting of: copper, aluminum, titanium, tungsten, nickel, palladium, gold, or an alloy containing at least one of the aforementioned metals, although other metals may be possible as well. For example, the stabilizing structure 304 (e.g. the substrate layer 304A of the stabilizing structure 304) may include, or may consist of, copper. The stabilizing structure 304 including, or consisting of, the metal or metal alloy may be configured to cool a chip that may be included in a chip arrangement manufactured by means of method 200. The stabilizing structure 304 including, or consisting of, the metal or metal alloy may, for example, be configured to improve (e.g. optimize) mechanical and/or thermal and/or electrical properties of a chip arrangement manufactured by means of method 200.

The stabilizing structure 304 (e.g. the substrate layer 304A of the stabilizing structure 304) may include, or may consist of, a ceramic material. The stabilizing structure 304 including, or consisting of, the ceramic material may, for example, be configured to electrically and/or thermally isolate a chip that may be included in a chip arrangement manufactured by means of method 200. The stabilizing structure 304 including, or consisting of, the ceramic material may, for example, be configured to seal a chip that may be included in a chip arrangement manufactured by means of method 200. The stabilizing structure 304 including, or consisting of, the ceramic material may, for example, be configured to optimize mechanical and/or thermal and/or electrical properties of a chip arrangement manufactured by means of method 200.

FIG. 3C shows a cross-sectional view 303 of a chip 306 disposed next to the stabilizing structure 304 and over the carrier 302.

Only two chips 306 are shown as an example, however the number of chips may be less than two (e.g. one) or greater than two, and may, for example, be three, four, five, six, seven, eight, nine, or on the order of tens, or even more chips.

The chip 306 may, for example, be a chip used for MEMS and/or logic and/or memory and/or power applications, although chips used for other applications may be possible as well.

As shown in FIG. 3C, chip 306 may include a first side 306a and a second side 306b opposite the first side 306a. The first side 306a and the second side 306b of the chip 306 may include, or may be, a frontside and a backside of the chip 306, respectively. By way of another example, the first side 306a of the chip 306 may include, or may be, an active side of the chip 306.

The chip 306 may include at least one contact 306c. The at least one contact 306c of the chip 306 may, for example, provide an interface (e.g. an electrical and/or thermal interface) for the chip 306. For example, signals (e.g. electrical signals, power supply potentials, ground potentials, etc.) may be exchanged with the chip 306 via the at least one contact 306c. By way of another example, heat may be conducted away from the chip 306 by means of the at least one contact 306c.

The at least one contact 306c of the chip 306 may, for example, be disposed at the first side 306a (e.g. active side), the second side 306b (e.g. backside), or both. For example, the at least one contact 306c may include, or may be, a metallization layer which may, for example, be disposed over the second side 306b (backside) of the chip 306. In the example shown in FIG. 3C, the at least one contact 306c may be disposed at the first side 306a (e.g. active side) and the second side 306b (e.g. backside) of the chip 306 (the at least one contact 306c disposed at the second side 306b is not shown in FIG. 3C). In another example, the at least one contact 306c may be disposed at one of the first side 306a and the second side 306b of the chip 306

In the example shown in FIG. 3C, the first side 306a (e.g. active side) of the chip 306 may face the carrier 302 and/or may be in contact (e.g. physical contact) with the carrier 302. Such an arrangement of the chip 306 may, for example, be referred to as a face-down arrangement of the chip 306.

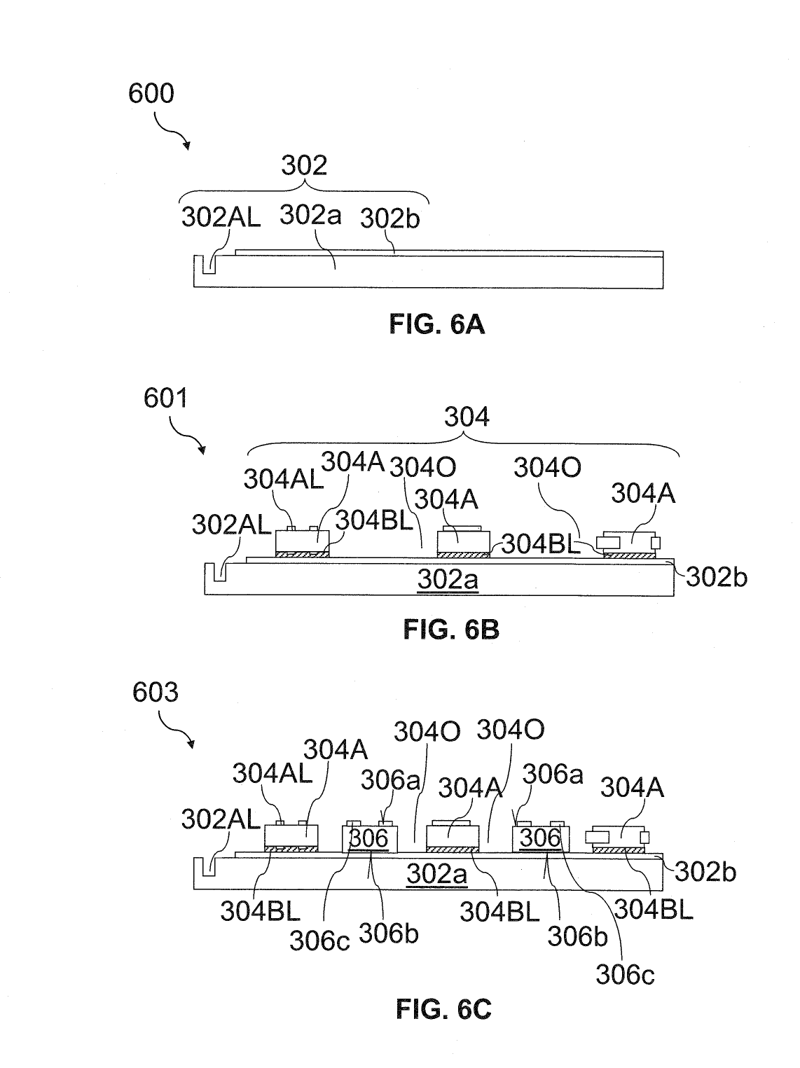

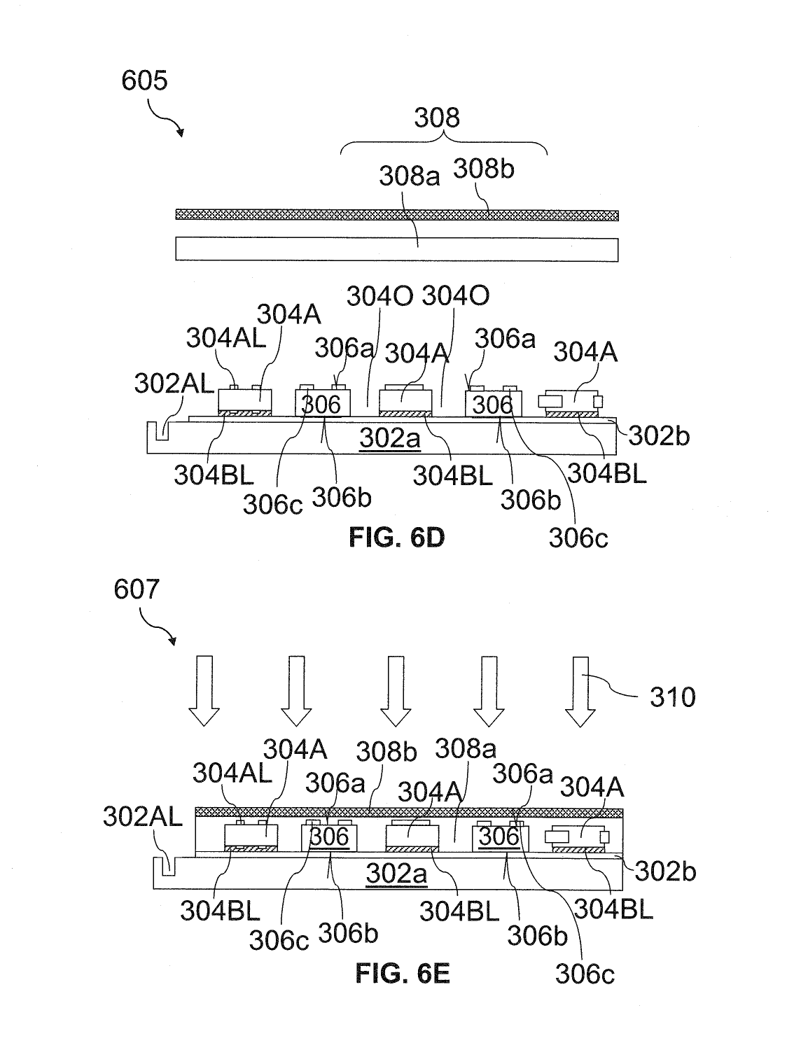

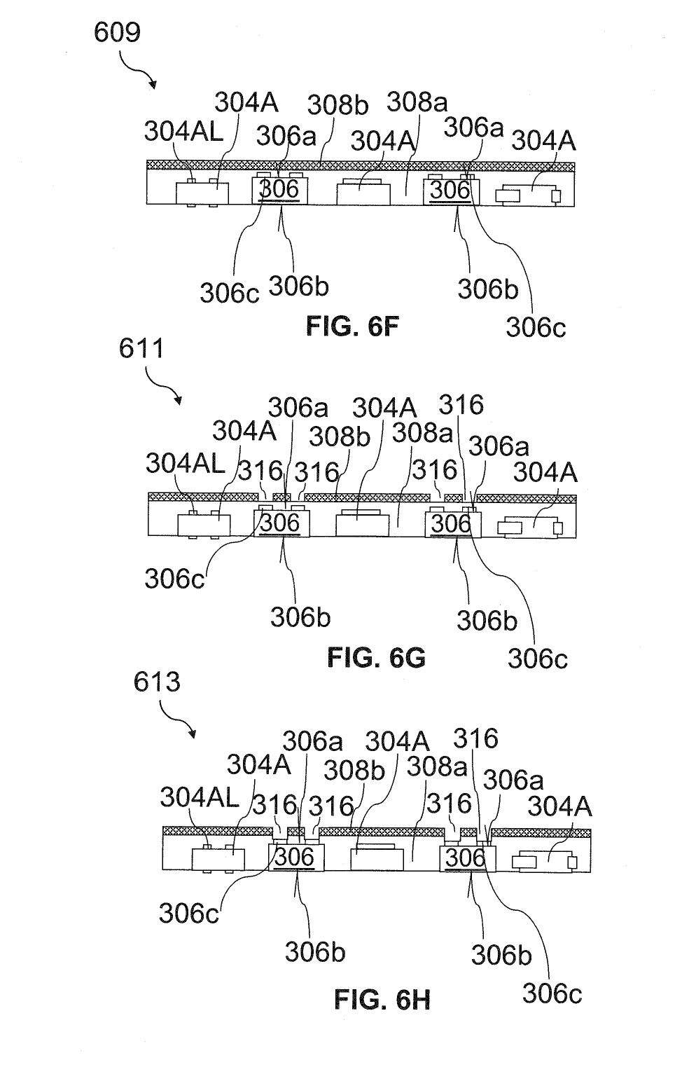

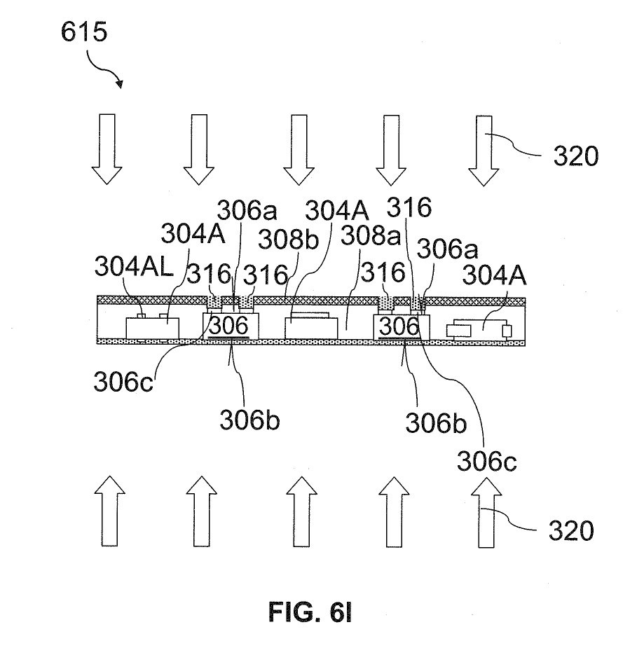

In another example, the second side 306b (e.g. backside) of the chip 306 may face the carrier 302 and/or may be in contact (e.g. physical contact) with the carrier 302 (e.g. see description below in respect of FIG. 6C). In this example, such an arrangement of the chip 306 may be referred to as a face-up arrangement of the chip 306.

As shown in FIG. 3C, the chip 306 may be disposed over the adhesive layer 302b of the carrier 302. Accordingly, disposing the stabilizing structure 304 and the chip 306 next to each other and over the carrier 302 may include disposing the stabilizing structure 304 and the chip 306 next to each other and over the adhesive layer 302b of the carrier 302.

As described above, the stabilizing structure 304 may include the at least one alignment mark 304AL and the carrier 302 may include the at least one alignment mark 302AL. In this regard, disposing the chip 306 and the stabilizing structure 304 next to each other and over the carrier 302 may include aligning the chip 306 to the stabilizing structure 304 by means of the at least one alignment mark 304AL and/or the at least one alignment mark 302AL, and disposing the chip 306 next to the stabilizing structure 304 and over the carrier 302. In other words, the chip 306 may be aligned (e.g. accurately aligned) by means of the at least one alignment mark 304AL of the stabilizing structure 304 and/or the at least one alignment mark 302AL of the carrier 302.

In the example shown in FIG. 3C, each of the one or more chips 306 may be mounted on a large carrier 302 (e.g. 300×400 mm²) and aligned using same aligning marks (e.g. of the stabilizing structure 304 and/or the carrier 302). Accordingly, the aligning accuracy may be good all over an entire area of the carrier 302 (e.g. the whole panel area).

As described above, FIG. 3A to FIG. 3C show an example in which the stabilizing structure 304 may be disposed over the carrier 302 (e.g. as shown in FIG. 3B), and the chip 306 may subsequently be disposed next to the stabilizing structure 304 and over the carrier 302 (e.g. as shown in FIG. 3C). However, in another example, the chip 306 may be disposed over the carrier 302, and the stabilizing structure 304 may subsequently be disposed next to the chip 306 and over the carrier 302. In such an example, the chip 306 may be aligned to the carrier 302 by means of the at least one alignment mark 302AL of the carrier 302. The stabilizing structure 304 may subsequently be aligned to the chip 306 and/or the carrier 302 by means of the at least one alignment mark 302AL of the carrier 302 and/or the at least one alignment mark 304AL of the stabilizing structure 304.

As described above, the stabilizing structure 304 may include the thru-opening 304O. In this regard, disposing the chip 306 and the stabilizing structure 304 next to each other and over the carrier 302 may include disposing the chip 306 within the thru-opening 304O of the stabilizing structure 304 and over the carrier 302, as shown in FIG. 3C.

The examples shown in FIG. 3A to FIG. 3C may, for example, be identified with “disposing a stabilizing structure and a chip including at least one contact next to each other and over a carrier” disclosed in 202 of method 200.

FIG. 3D and FIG. 3E show cross-sectional views 305 and 307 of the chip 306 and the stabilizing structure 304 encapsulated by means of an encapsulating structure 308.

The examples shown in FIG. 3D and FIG. 3E may, for example, be identified with “encapsulating the chip and the stabilizing structure by means of an encapsulating structure” disclosed in 204 of method 200.

As shown in FIG. 3D in a view 305, encapsulating the chip 306 and the stabilizing structure 304 may include laying-up the encapsulating structure 308 over the chip 306, the stabilizing structure 304, and the carrier 302.

The encapsulating structure 308 may include an insulating layer 308a. The encapsulating structure 308 shown in FIG. 3D may additionally include a conductive layer 308b. However, in another example, the encapsulating structure 308 may include the insulating layer 308a only. As illustrated in the example shown in FIG. 3D, the insulating layer 308a may be disposed between the chip 306 and the conductive layer 308b.

The encapsulating structure 308 (e.g. the insulating layer 308a of the encapsulating structure 308) may include, or may consist of, at least one of a molding material, a prepreg material, a resin material, and a laminate material (e.g. an uncured laminate material), although other materials may be possible as well.

The encapsulating structure 308 (e.g. the conductive layer 308b of the encapsulating structure 308) may include, or may consist of, an electrically conductive material and/or a thermally conductive material. For example, the encapsulating structure 308 (e.g. the conductive layer 308b of the encapsulating structure 308) may include, or may consist of, a metal or metal alloy. The metal may include at least one metal selected from a group of metals, the group consisting of: copper, aluminum, titanium, tungsten, nickel, palladium, gold, or an alloy containing at least one of the aforementioned metals, although other metals may be possible as well. For example, the encapsulating structure 308 (e.g. the conductive layer 308b of the encapsulating structure 308) may include, or may consist of, copper or a copper alloy.

As described above in relation to the chip 306 shown in FIG. 3C, the at least one contact 306c may be disposed at the first side 306a (e.g. active side) and/or the second side 306b (e.g. backside) of the chip 306. The conductive layer 308b of the encapsulating structure 308 may be suitable for forming a subsequent electrical and/or thermal connection with the stabilizing structure 304 and/or the chip 306. For example, the conductive layer 308b of the encapsulating structure 308 may be at least a part of an electrical and/or thermal connection to the at least one contact 306c disposed at the second side 306b of the chip 306.

As shown in FIG. 3E in a view 307, encapsulating the chip 306 and the stabilizing structure 304 by means of the encapsulating structure 308 may include applying heat and pressure (indicated by arrows 310) to fuse the encapsulating structure 308, the chip 306, and the stabilizing structure 304 together. Applying heat and pressure (indicated by arrows 310) may include, or may be, a lamination process. In other words, encapsulating the chip 306 and the stabilizing structure 304 by means of the encapsulating structure 308 may include, or may consist of, a lamination process.

The applied heat and/or pressure (indicated by arrows 310) may soften (e.g. melt) the encapsulating structure 308 (e.g. the insulating layer 308a of the encapsulating structure 308) such that the encapsulating structure 308 (e.g. the insulating layer 308a of the encapsulating structure 308) flows into and fills the thru-opening 304O of the stabilizing structure 304. At least a portion of the encapsulating structure 308 (e.g. at least a portion of the insulating layer 308a and/or the conductive layer 308b of the encapsulating structure 308) may be additionally disposed over the chip 306 and the stabilizing structure 304 after the application of heat and/or pressure, as shown in FIG. 3E.

FIG. 3F to FIG. 3K show cross-sectional views illustrating the forming of at least one electrically conductive connection to the at least one contact 306c of the chip 306.

The examples shown in FIG. 3F to FIG. 3K may, for example, be identified with “forming an electrically conductive connection to the at least one contact of the chip” disclosed in 206 of method 200.

As shown in FIG. 3F in a view 309, forming the at least one electrically conductive connection to the at least one contact 306c of the chip 306 may include removing the carrier 302 e.g. to expose the at least one contact 306c of the chip 306. For example, the at least one contact 306c of the chip 306 may be visible and/or exposed with the removal of the carrier 302. In the example shown in FIG. 3F, the at least one contact 306c disposed at the first side 306a (e.g. active side) of the chip 306 may be visible and/or exposed by the removal of the carrier 302. In the example shown in FIG. 3F, the bonding layer 304BL may be removed with the carrier 302 (e.g. by means of at least one of dissolving, peeling off, and curing).

As described above, the carrier 302 may include the plate 302a and the adhesive layer 302b. Accordingly, removing the carrier 302 may include removing the plate 302a and the adhesive layer 302b of the carrier 302, e.g. to expose the at least one contact 306c of the chip 306. Removing the adhesive layer 302b of the carrier 302 may include at least one of dissolving the adhesive layer 302b (e.g. by means of a solvent), peeling off the adhesive layer 302b, and curing the adhesive layer 302b. For example, as described above, the carrier 302 (e.g. the adhesive layer 302b of the carrier 302) may include, or may consist of, a double-sided sticky tape with thermo-release properties (namely, elements may be separated and/or released from the double-sided sticky tape by means of heating and/or curing the double-sided sticky tape). In such an example, the adhesive layer 302b may be cured, thus separating the chip 306 and the stabilizing structure 304 from the carrier 302. The stabilizing structure 304 and the chip 306 may be held in place by means of the encapsulating structure 308 (e.g. the insulating layer 308a of the encapsulating structure 308).

As shown in FIG. 3G in a view 311, forming the electrically conductive connection to the at least one contact 306c of the chip 306 may include disposing a second conductive layer 312b over the at least one contact 306c of the chip 306 (e.g. the at least one exposed contact 306c of the chip 306). In the example shown in FIG. 3G, the second conductive layer 312b may be disposed over the at least one contact 306c disposed at the first side 306a of the chip 306, which may be exposed and/or visible (e.g. due to the removal of the carrier 302). Since the stabilizing structure 304 is disposed next to the chip 306, the second conductive layer 312b may be disposed over the stabilizing structure 304 as well.

The second conductive layer 312b may include, or may consist of, an electrically conductive material and/or a thermally conductive material. For example, the second conductive layer 312b may include, or may consist of, a metal or metal alloy. The metal may include at least one metal selected from a group of metals, the group consisting of: copper, aluminum, titanium, tungsten, nickel, palladium, gold, or an alloy containing at least one of the aforementioned metals, although other metals may be possible as well. For example, the second conductive layer 312b may include, or may consist of, copper or a copper alloy.

As shown in FIG. 3G, disposing the second conductive layer 312b over the at least one contact 306c of the chip 306 may include disposing a second insulating layer 312a between the second conductive layer 312b and the at least one contact 306c of the chip 306 (e.g. the exposed contact of the chip, e.g. the at least one contact 306c disposed at the first side 306a of the chip 306).

The second insulating layer 312a may include, or may consist of, at least one of a molding material, a prepreg material, a resin material, and a laminate material (e.g. an uncured laminate material), although other materials may be possible as well.

As described above in relation to the chip 306 shown in FIG. 3C, the at least one contact 306c may be disposed at the first side 306a (e.g. active side) and/or the second side 306b (e.g. backside) of the chip 306. In the example shown in FIG. 3C, the second conductive layer 312b may be suitable for forming the electrically conductive connection with the stabilizing structure 304 and/or the chip 306 (e.g. the at least one contact 306c disposed at the first side 306a of the chip 306).

As shown in FIG. 3H in a view 313, disposing the second conductive layer 312b over the at least one contact 306c of the chip 306 (e.g. the at least one contact 306c disposed at the first side 306a of the chip 306) may include applying heat and pressure (indicated by arrows 314) to fuse the second conductive layer 312b, the second insulating layer 312a, the encapsulating structure 308, the chip 306, and the stabilizing structure 304 together. Applying heat and pressure (indicated by arrows 314) may include, or may be, a lamination process. In other words, disposing the second conductive layer 312b over the at least one contact 306c of the chip 306 (e.g. the at least one contact 306c disposed at the first side 306a of the chip 306) may include, or may consist of, a lamination process.

A distance D between the at least one contact 306c of the chip 306 (e.g. the at least one exposed contact 306c of the chip 306c) and the second conducting layer 312b may be at least substantially equal over a lateral extent of the chip arrangement shown in FIG. 3H. The distance D may be easily controlled by controlling a thickness of the second insulating layer 312a.

As described above, an electrically conductive connection may be formed with the at least one contact 306c of the chip 306. As described above, the at least one contact 306c of the chip 306 shown in FIG. 3C to FIG. 3K may be disposed at the first side 306a and the second side 306b of the chip 306. Accordingly, the electrically conductive connection may be formed with the first side 306a and the second side 306b of the chip 306. In another example, the electrically conductive connection may be formed to the first side 306a or the second side 306b of the chip 306, depending on where the at least one contact 306c of the chip 306 may be disposed.

As shown in FIG. 3I in a view 315 and FIG. 3J in a view 317, forming the electrically conductive connection to the at least one contact 306c of the chip 306 may include forming at least one opening 316 in the encapsulating structure 308 to expose the at least one contact 306c of the chip 306 (e.g. the at least one contact 306c disposed at the second side 306b of the chip 306). For example, the at least one opening 316 may be formed in the conductive layer 308b of the encapsulating structure 308, as shown in FIG. 3I. The at least one opening 316 may be formed in the encapsulating structure 308 by means of an etching process (e.g. a micro-etching process, e.g. a micro-via etching process) and/or a drilling process (e.g. a micro-drilling process).

The at least one opening 316 may be subsequently deepened (e.g. extended through the insulating layer 308a of the encapsulating structure 308) to expose the at least one contact 306c of the chip 306 (e.g. the at least one contact 306c disposed at the second side 306b of the chip 306), as shown in FIG. 3J. The at least one opening 316 may be deepened by means of a cleaning process and/or a drilling process (e.g. via cleaning and/or drilling process, e.g. a micro-via cleaning and/or drilling process).

As shown in FIG. 3I in a view 315 and FIG. 3J in a view 317, forming the electrically conductive connection to the at least one contact 306c of the chip 306 may include forming at least one opening 318 in the second conductive layer 312b and the second insulating layer 312a to expose the at least one contact 306c of the chip 306 (e.g. the at least one contact 306c disposed at the first side 306a of the chip 306). For example, the at least one opening 318 may be formed in the second conductive layer 312b, as shown in FIG. 3I. The at least one opening 318 may be formed in the second conductive layer 312b by means of an etching process (e.g. a micro-etching process, e.g. a micro-via etching process) and/or a drilling process (e.g. a micro-drilling process).

The at least one opening 318 may be subsequently deepened (e.g. extended through the second insulating layer 312a) to expose the at least one contact 306c of the chip 306 (e.g. the at least one contact 306c disposed at the first side 306a of the chip 306), as shown in FIG. 3J. The at least one opening 318 may be deepened by means of a cleaning process and/or a drilling process (e.g. via cleaning and/or drilling process, e.g. a micro-via cleaning and/or drilling process).

In the examples shown in FIG. 3I and FIG. 3J, at least one opening 323 may be formed to expose at least a part of the stabilizing structure 304. The at least one opening 323 may be formed and/or deepened by means of similar processes used in relation to the at least one opening 316 and the at least one opening 318. In another example, however, there may not be an opening that may expose at least a part of the stabilizing structure 304.

Forming the at least one opening 316 and/or 318 and/or 323 (e.g. by means of an etching process and/or micro-via cleaning and/or drilling process) may include using the at least one alignment mark 304AL of the stabilizing structure, which may improve accuracy and/or precision of the etching process and/or micro-via cleaning and/or drilling process.

As shown in FIG. 3K in a view 319, forming the electrically conductive connection to the at least one contact 306c of the chip 306 may include a plating process (indicated by arrows 320). In one or more examples, a seed metal or seed metal alloy (e.g. seed copper) may be sputtered prior to or as part of the plating process (indicated by arrows 320). The plating process (indicated by arrows 320) may, for example, fill the at least one opening 316, 318 and/or 323 with an electrically conductive material.

In the example shown in FIG. 3K, the electrically conductive connection between the second conductive layer 312b and the at least one contact 306c of the chip 306 (e.g. the at least one contact 306c disposed at the first side 306a of the chip 306) may be formed by means of the plating process (indicated by arrows 320). By way of another example, the electrically conductive connection between the conductive layer 308b of the encapsulating structure 308 and the at least one contact 306c of the chip 306 (e.g. the at least one contact 306c disposed at the second side 306b of the chip 306) may be formed by means of the plating process (indicated by arrows 320).

In the example shown in FIG. 3K, an electrically conductive connection may also be formed between the conductive layer 308b of the encapsulating structure 308 and the stabilizing structure 304 by means of the plating process (indicated by arrows 320).

The plating process (indicated by arrows 320) for forming the electrically conductive connection to the at least one contact 306c of the chip 306 may include an electroless plating process or an electrochemical plating process or a direct metallization process.

Forming the electrically conductive connection to the at least one contact 306c of the chip 306 may include patterning the conductive layer 308a of the encapsulating structure 308 and/or the second conductive layer 312b, e.g. subsequent to the plating process shown in FIG. 3K. Patterning the conductive layer 308a of the encapsulating structure 308 and/or the second conductive layer 312b may include, or may consist of, an etching process (e.g. a dry and/or wet etch process). The patterning process may, for example, make use of at least one alignment mark, which may improve accuracy and/or precision of the patterning process. The at least one alignment mark may, for example, be disposed at the conductive layer 308b and/or the second conductive layer 312b. This alignment mark may, for example, be formed by means of reproducing the at least one alignment mark 304AL of the stabilizing structure 304 and/or the at least one alignment mark 302AL of the carrier 302, e.g. prior to the removal of the carrier 302.

As described above, the patterning process may be performed subsequent to the plating process shown in FIG. 3K. However, in another example, the at least one opening 316 and/or 318 and/or 323 may be filled with electrically conductive material by means of a structured deposition process and/or a selective plating process. For example, a patterned resist material (e.g. a photo-resist material) may be formed over the conductive layer 308b of the encapsulating structure 308 and/or the second conductive layer 312b, wherein the at least one opening 316 and/or 318 and/or 323 may be left exposed (namely, not covered by the patterned resist material). Subsequently, a plating process may be performed, which may form the electrically conductive connection to the at least one contact 306c of the chip 306. In such an example, the electrically conductive connection may be formed (e.g. by means of selective deposition and/or selective plating) over a part of the chip 306 and/or the stabilizing structure 304 that is not covered by the patterned resist material.

FIG. 6A to FIG. 6I show a process-flow illustrating another example of the method 200 shown in FIG. 2.

Reference signs in FIG. 6A to FIG. 6I that are the same as in FIG. 3A to FIG. 3K denote the same or similar elements as in FIG. 3A to FIG. 3K. Thus, those elements will not be described in detail again here; reference is made to the description above. Differences between FIG. 6A to FIG. 6I and FIG. 3A to FIG. 3K are described below.

As shown in FIG. 6C in a view 603, the chip 306 may be arranged in a face-up arrangement. In other words, the second side 306b (e.g. backside) of the chip 306 may face and/or may be in contact (e.g. physical contact) with the carrier 302.

As shown in FIG. 6F in a view 609, forming the at least one electrically conductive connection to the at least one contact 306c of the chip 306 may include removing the carrier 302 e.g. to expose the at least one contact 306c of the chip 306. In the example shown in FIG. 6F, the at least one contact 306c disposed at the second side 306b (e.g. backside) of the chip 306 may be exposed with the removal of the carrier 302.

As described above, the at least one contact 306c disposed at the second side 306b (e.g. backside) of the chip 306 may include, or may be, a metallization layer. Accordingly, in the example shown in FIG. 6F, the metallization layer of the chip 306 may be exposed with the removal of the carrier 302.

As shown in FIG. 6G in a view 611 and FIG. 6H in a view 613, forming the electrically conductive connection to the at least one contact 306c of the chip 306 may include forming at least one opening 316 in the encapsulating structure 308 to expose the at least one contact 306c of the chip 306 (e.g. the at least one contact 306c disposed at the first side 306a of the chip 306). For example, the at least one opening 316 may be formed in the conductive layer 308b of the encapsulating structure 308, as shown in FIG. 6G. The at least one opening 316 may be formed in the encapsulating structure 308 by means of an etching process (e.g. a micro-etching process, e.g. a micro-via etching process) and/or a drilling process (e.g. a micro-drilling process).

The at least one opening 316 may be subsequently deepened (e.g. extended through the insulating layer 308a of the encapsulating structure 308) to expose the at least one contact 306c of the chip 306 (e.g. the at least one contact 306c disposed at the first side 306a of the chip 306), as shown in FIG. 6H. The at least one opening 316 may be deepened by means of a cleaning process and/or a drilling process (e.g. via cleaning and/or drilling process, e.g. a micro-via cleaning and/or drilling process).

In the example shown in FIG. 6G and FIG. 6H, there may not be an opening formed to expose at least a part of the stabilizing structure 304. However, in another example, the at least one opening 323 may be formed to expose at least a part of the stabilizing structure 304.

As shown in FIG. 6I in a view 615, forming the electrically conductive connection to the at least one contact 306c of the chip 306 may include the plating process (indicated by arrows 320). For example, the electrically conductive connection between the conductive layer 308b of the encapsulating structure 308 and the at least one contact 306c of the chip 306 (e.g. the at least one contact 306c disposed at the first side 306a of the chip 306) may be formed by means of the plating process (indicated by arrows 320). By way of another example, the electrically conductive connection to the at least one contact 306c disposed at the second side 306b of the chip 306 may be formed by means of the plating process (indicated by arrows 320).

The plating process (indicated by arrows 320) for forming the electrically conductive connection to the at least one contact 306c of the chip 306 may include an electroless plating process or an electrochemical plating process or a direct metallization process.

As described above in relation to the example shown in FIG. 3A to FIG. 3K, forming the electrically conductive connection to the at least one contact 306c of the chip 306 may include patterning the plated electrically conductive connection. The features of the patterning process described above may be analogously applicable to the example shown in FIG. 6A to FIG. 6I.

FIG. 7A to FIG. 7K show a process-flow illustrating yet another example of the method 200 shown in FIG. 2.

Reference signs in FIG. 7A to FIG. 7K that are the same as in FIG. 3A to FIG. 3K denote the same or similar elements as in FIG. 3A to FIG. 3K. Thus, those elements will not be described in detail again here; reference is made to the description above. Differences between FIG. 7A to FIG. 7K and FIG. 3A to FIG. 3K are described below.

As shown in FIG. 7B in a view 701, the chip arrangement may include a plurality of chips 306. At least one chip 306 may be arranged in a face-up arrangement (namely, the second side 306b may face and/or be in contact (e.g. physical contact) with the carrier 302), and at least one other chip 306 may be arranged in a face-down arrangement (namely, the first side 306a may face and/or be in contact (e.g. physical contact) with the carrier 302).

As shown in FIG. 7B, the chip 306 may be disposed over the carrier 302 prior to the stabilizing structure 304. In such an example, the at least one alignment mark 302AL of the carrier may be used to align the chip 306 to the carrier 302.

As shown in FIG. 7C in a view 703, the stabilizing structure 304 may be disposed subsequent to disposing the chip 306. In such an example, the least one alignment mark 302AL of the carrier may be used to align the stabilizing structure 304. For example, the at least one alignment mark 304AL of the stabilizing structure 304 and the at least one alignment mark 302AL of the carrier 302 may be used to align the stabilizing structure 304.

FIG. 7D to FIG. 7K show a process-flow, which may be performed using processes described above in respect of FIG. 3D to FIG. 3K.

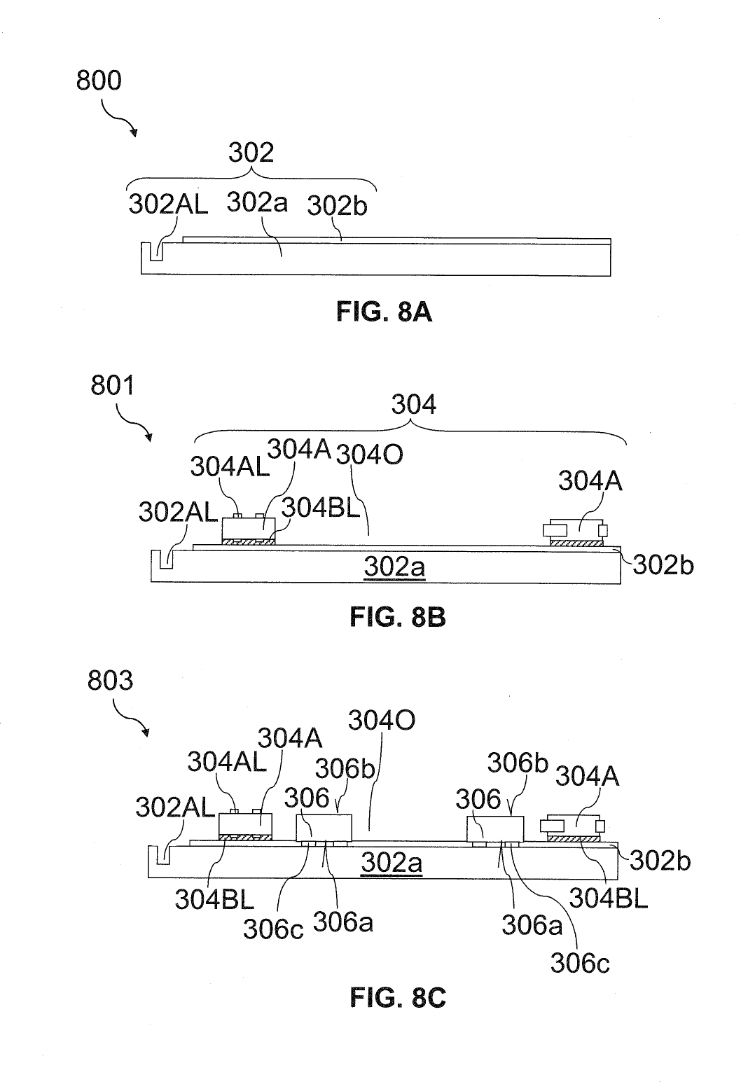

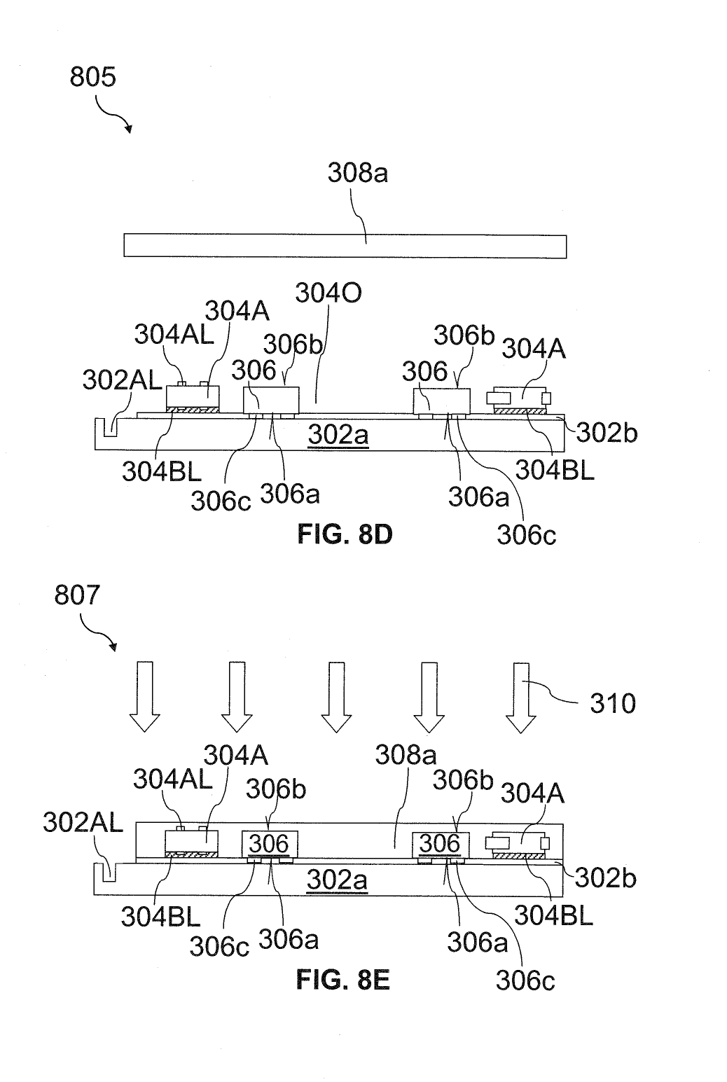

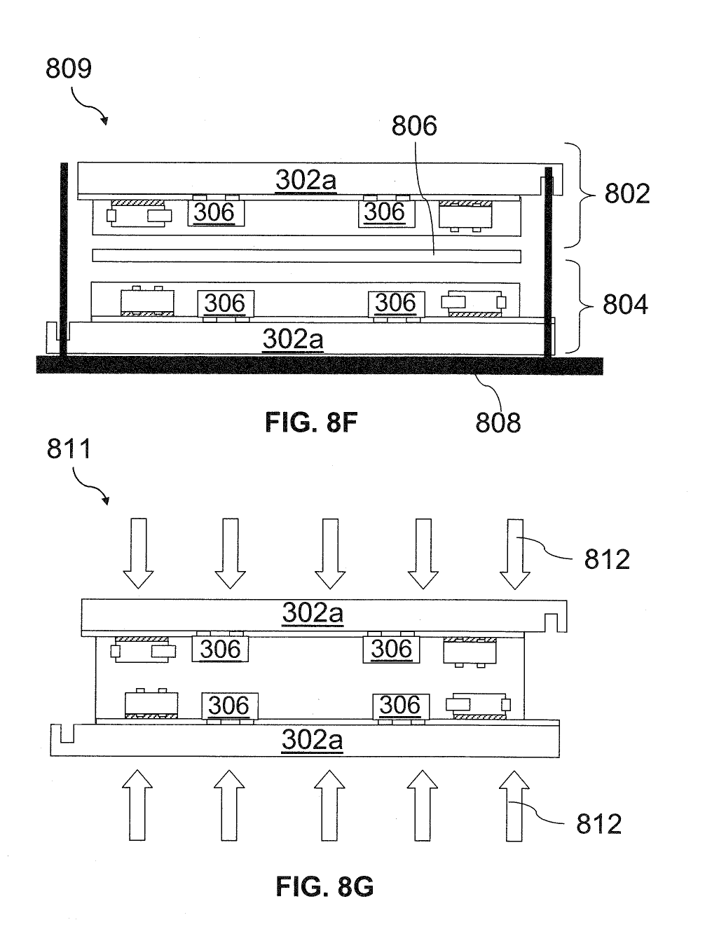

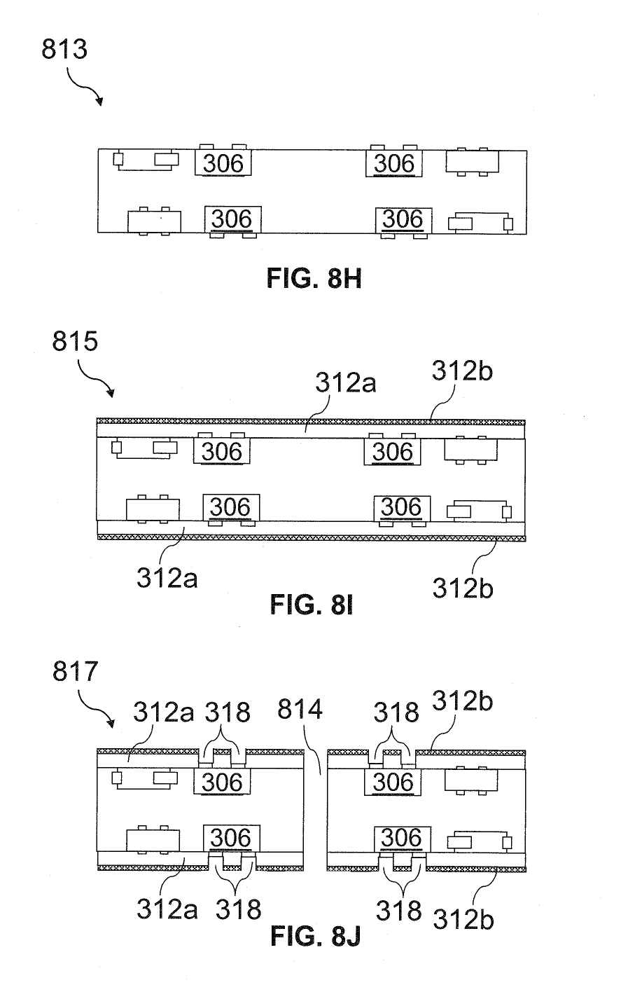

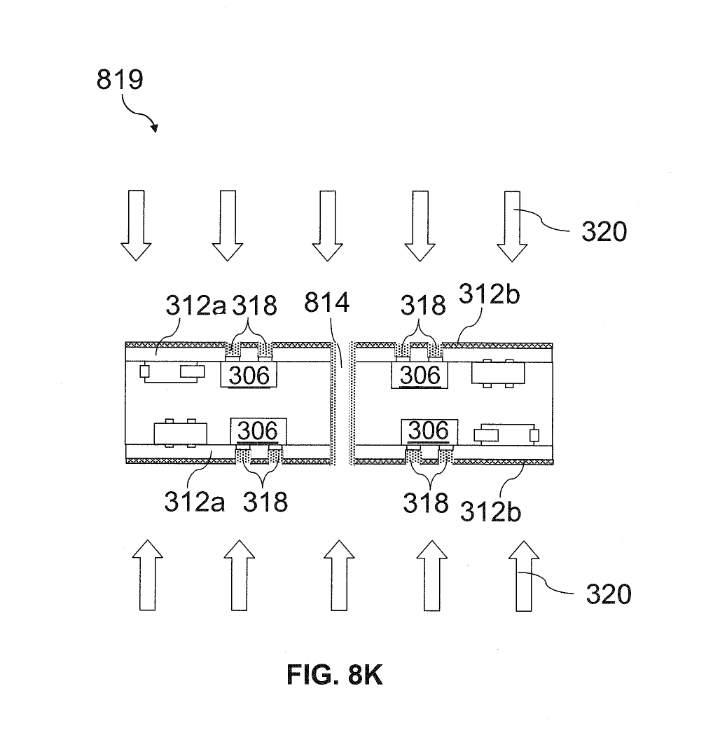

FIG. 8A to FIG. 8K show a process-flow illustrating an example of the method 200 shown in FIG. 2 applied to a manufacture of a three-dimensional (3D) chip arrangement.

Reference signs in FIG. 8A to FIG. 8K that are the same as in FIG. 7A to FIG. 7K denote the same or similar elements as in FIG. 7A to FIG. 7K. Thus, those elements will not be described in detail again here; reference is made to the description above. Differences between FIG. 8A to FIG. 8K and FIG. 7A to FIG. 7K are described below.

As shown in FIG. 8F, a first module 802 may be arranged over a second module 804. A third insulating layer 806 may be disposed between the first module 802 and the second module 804.

The first and second modules 802, 804 may each include, or may be, the chip arrangement shown in FIG. 8E. Namely, each of the first and second modules 802, 804 may include the carrier 302, the chip 306, the stabilizing structure 304, and the encapsulating structure 308 (e.g. which may include the insulating layer 308a, and which may be free from the conducting layer 308b).

As shown in FIG. 8F, the first module 802, the second module 804, and the third insulating layer 806 may be disposed over a workpiece 808. The first module 802, the second module 804, and the third insulating layer 806 may be aligned to each other by means of the at least one alignment mark 302AL of the carrier 302 of the first module 802 and/or the second module 804.

As shown in FIG. 8G in a view 811, the first module 802, the second module 804, and the third insulating layer 806 may be pressed together (indicated by arrows 812) to form a 3D chip arrangement.

As shown in FIG. 8H in a view 813, the respective carriers of the first and second modules 802, 804 may be removed to expose the at least one contact 306c of the chip 306 of the first module 802 and the second module 804.

As shown in FIG. 8I in a view 815, forming the electrically conductive connection to the at least one contact 306c of the chip 306 may include disposing the second conductive layer 312b over the at least one contact 306c of the chip 306 of the first and second modules 802, 804. In the example shown in FIG. 8I, the second conductive layer 312b may be disposed over the at least one contact 306c disposed at the first side 306a of the chip 306 of the first and second modules 802, 804. As shown in FIG. 8I, disposing the second conductive layer 312b over the at least one contact 306c of the chip 306 may include disposing the second insulating layer 312a between the second conductive layer 312b and the at least one contact 306c of the chip 306.

As shown in FIG. 8J in a view 817, forming the electrically conductive connection to the at least one contact 306c of the chip 306 may include forming at least one opening 318 in the second conductive layer 312b and the second insulating layer 312a to expose the at least one contact 306c of the chip 306 (e.g. the at least one contact 306c disposed at the first side 306a of the chip 306). The at least one opening 318 may be formed and/or deepened by means of the processes described above in respect of FIG. 3I and FIG. 3J.

Forming the electrically conductive connection to the at least one contact 306c of the chip 306 may include forming at least one through-via 814 in the 3D chip arrangement. The at least one through-via 814 may be formed by means of similar or identical processes as those described above in respect of the at least one opening 316, 318 and/or 323.

As shown in FIG. 8K in a view 819, forming the electrically conductive connection to the at least one contact 306c of the chip 306 may include a plating process (indicated by arrows 320). For example, the electrically conductive connection between the conductive layer 308b of the encapsulating structure 308 and the at least one contact 306c of the chip 306 (e.g. the at least one contact 306c disposed at the first side 306a of the chip 306) of the first and second modules 802, 804 may be formed by means of the plating process (indicated by arrows 320). The plating process (indicated by arrows 320) may line the at least one through-via 814 and/or fill the at least one opening 318 with an electrically conductive material.

The plated electrically conductive connection may be patterned, as described above in relation to FIG. 3K.

As described above, a conventional method for manufacturing a chip arrangement may include embedding a chip inside a prepreg, and may include bonding chips that may be disposed face-down on a copper foil with non-conductive adhesives. Compared with such an example, the method 200 may avoid the disadvantages of such a conventional method (e.g. HAST problems, delamination, etc.) since the second insulating layer 312a between the second conductive layer 312b and the at least one contact 306c of the chip 306 (e.g. the at least one contact 306c disposed at the first side 306a of the chip 306) is formed after using vacuum lamination.

As described above, a conventional method for manufacturing a chip arrangement may include an eWLB manufacturing process. Compared with the eWLB manufacturing process, the method 200 may allow manufacturing double sided arrangements where the chip 306 may be arranged in a face-up and/or face-down arrangement. Compared with the eWLB manufacturing process, the method 200 may allow the forming of a plated electrical connection with the first side 306a and/or the second side 306b of the chip 306. Compared with the eWLB manufacturing process, the method 200 may allow the forming of an electrical connection with the second side 306b (e.g. backside) of the chip 306 by means of a plating process. Compared with the eWLB manufacturing process, the method 200 may allow the use of standard PCB material (e.g. standard reinforced PCB material), large panel size and low cost PCB manufacturing processes, instead of wafer level processes. This may be easy to incorporate and/or include in a standard PCB production.

As described above, a conventional method for manufacturing a chip arrangement may include the example shown in FIG. 1A to FIG. 1G. Compared with this example, the method 200 may allow manufacturing double sided arrangements where the chip 306 may be arranged in a face-up and/or face-down arrangement. Compared with the example shown in FIG. 1A to FIG. 1G, the method 200 may allow the forming of a plated electrical connection with the first side 306a and/or the second side 306b of the chip 306. Compared with the example shown in FIG. 1A to FIG. 1G, the method 200 may allow the forming of an electrical connection with the second side 306b (e.g. backside) of the chip 306 by means of a plating process. Compared with the example shown in FIG. 1A to FIG. 1G, the chip 306 may be aligned to the carrier 302 that may have a large size (e.g. same size as a production panel) using the at least one alignment mark 302AL of the carrier 302. Compared with the leadframe 102 shown in FIG. 1A to FIG. 1G which may, for example, be smaller (e.g. about 165×68 mm²), the method 200 may provide accurate alignment of the chip 306 to the carrier 302. Since a plurality of leadframes 102 may not be needed compared with the example shown in FIG. 1A to FIG. 1G, an effect of the method 200 may be reduction or prevention of additional tolerances between a plurality of leadframes 102 (which may also be referred to as sub-panels).

As described above, the chip 306 may be disposed in a face-down arrangement. In such an arrangement, a distance between the at least one contact 306c of the chip 306 and the second conducting layer 312b may be at least substantially equal over a lateral extent of the chip arrangement. The distance may be easily controlled by controlling a thickness of the second insulating layer 312a. This may allow for easier forming of the at least one opening 316, 318, and 323.

As compared with a conventional method for manufacturing a chip arrangement, the method 200 may allow arrangement of the chip 306 in a face-up or face-down arrangement, or both, and forming of an electrically conductive connection to the chip 306 from the first side 306a and/or the second side 306b, thus enabling a manufacture of a 3D chip arrangement.

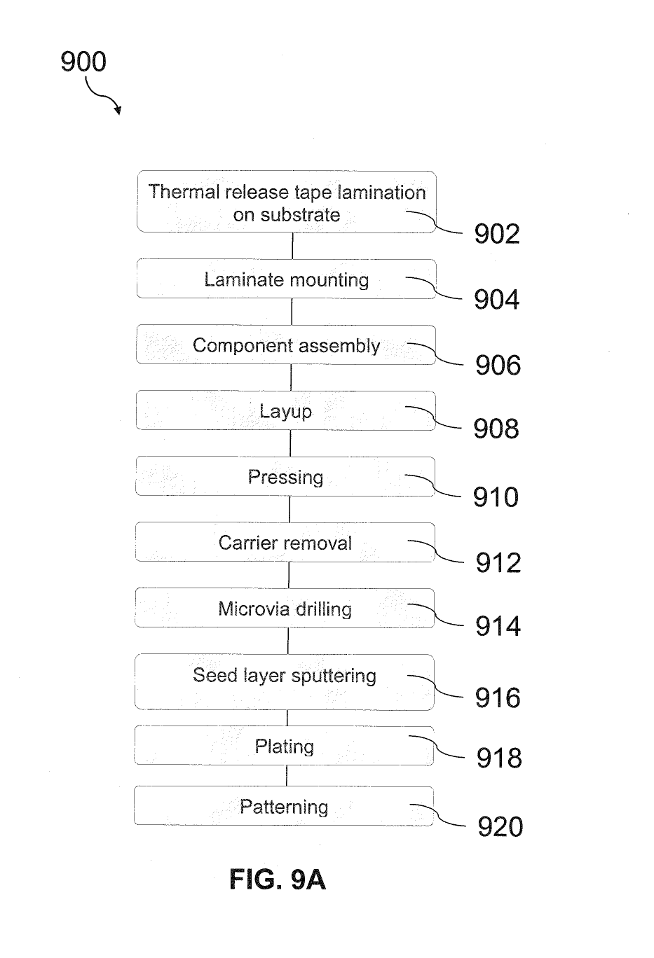

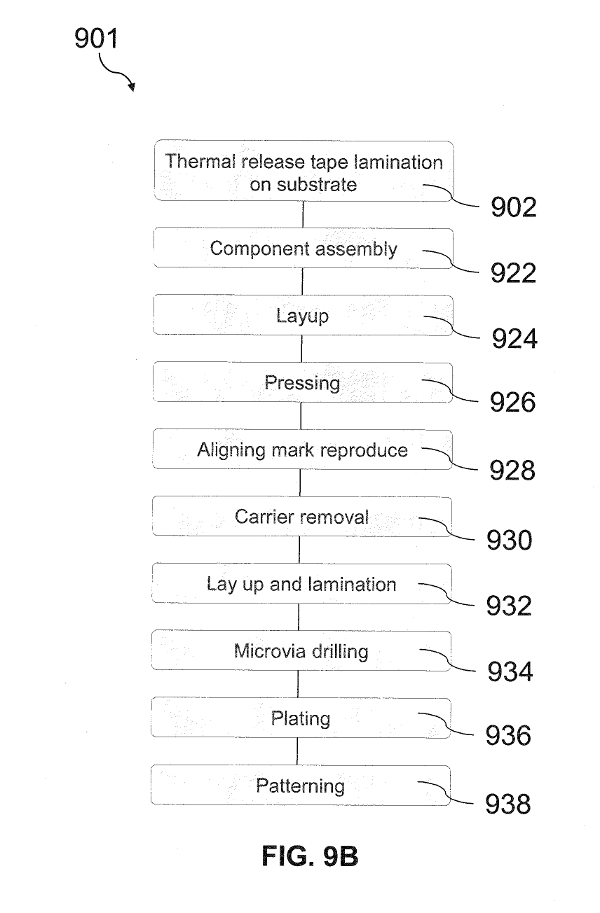

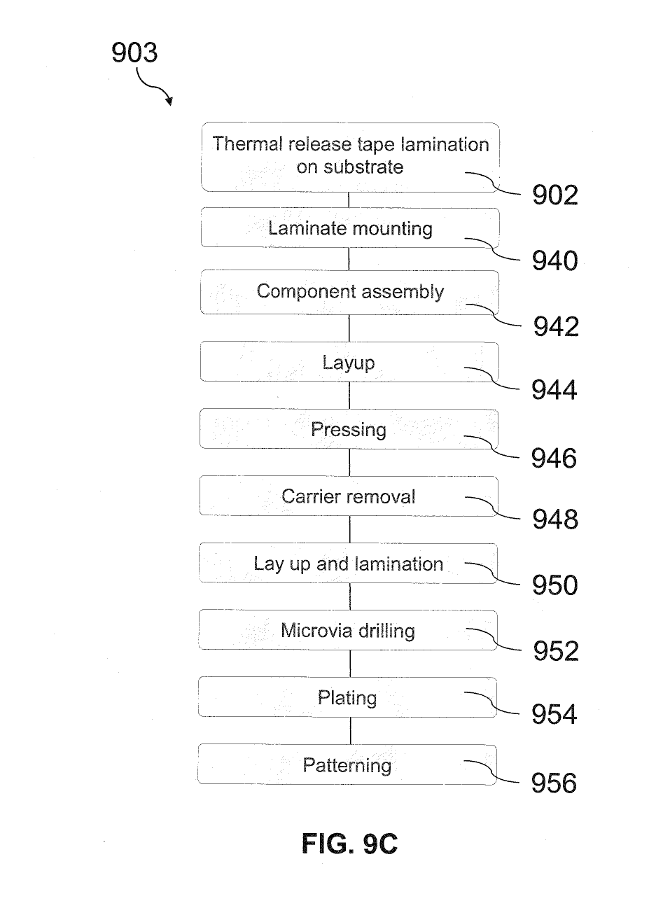

FIG. 9A to FIG. 9C show flow diagrams illustrating other examples of the method 200 shown in FIG. 2.

As an example, the flow diagram 900 shown in FIG. 9A shows a process 902, which may, for example, be identified with the process shown in FIG. 4A and FIG. 4B.

The process 904 shown in the flow diagram 900 of FIG. 9A may, for example, be identified with the process shown in FIG. 6B.

The process 906 shown in the flow diagram 900 of FIG. 9A may, for example, be identified with the process shown in FIG. 6C.

The process 908 shown in the flow diagram 900 of FIG. 9A may, for example, be identified with the process shown in FIG. 6D.

The process 910 shown in the flow diagram 900 of FIG. 9A may, for example, be identified with the process shown in FIG. 6E.

The process 912 shown in the flow diagram 900 of FIG. 9A may, for example, be identified with the process shown in FIG. 6F.

The process 914 shown in the flow diagram 900 of FIG. 9A may, for example, be identified with the processes shown in FIG. 6G and FIG. 6H.

The process 916 shown in the flow diagram 900 of FIG. 9A may, for example, be identified with the seed metal or seed metal alloy (e.g. seed copper) described above, which may be sputtered prior to or as part of the plating process (indicated by arrows 320).

The process 918 shown in the flow diagram 900 of FIG. 9A may, for example, be identified with the process shown in FIG. 6I.

The process 920 shown in the flow diagram 900 of FIG. 9A may, for example, be identified with the patterning process described above.

As another example, the flow diagram 901 shown in FIG. 9B shows a process 901, which may, for example, be identified with the process shown in FIG. 4A and FIG. 4B.

The process 922 shown in the flow diagram 901 of FIG. 9B may, for example, be identified with the process shown in FIG. 7B.

The process 924 shown in the flow diagram 901 of FIG. 9B may, for example, be identified with the processes shown in FIG. 7C and FIG. 7D.

The process 926 shown in the flow diagram 901 of FIG. 9B may, for example, be identified with the process shown in FIG. 7E.

The process 928 shown in the flow diagram 901 of FIG. 9B may, for example, indicate that the at least one alignment mark 302AL of the carrier 302 and/or the at least one alignment mark 304AL of the stabilizing structure 304 may be reproduced at (e.g. reproduced over a surface of) the encapsulating structure 308.

The process 930 shown in the flow diagram 901 of FIG. 9B may, for example, be identified with the process shown in FIG. 7F.

The process 932 shown in the flow diagram 901 of FIG. 9B may, for example, be identified with the processes shown in FIG. 7G and FIG. 7H.

The process 934 shown in the flow diagram 901 of FIG. 9B may, for example, be identified with the processes shown in FIG. 7I and FIG. 7J.

The process 936 shown in the flow diagram 901 of FIG. 9B may, for example, be identified with the process shown in FIG. 7K.

The process 938 shown in the flow diagram 901 of FIG. 9B may, for example, be identified with the patterning process described above.

As yet another example, the flow diagram 903 shown in FIG. 9C shows a process 902, which may, for example, be identified with the process shown in FIG. 4A and FIG. 4B.

The process 940 shown in the flow diagram 903 of FIG. 9C may, for example, be identified with the process shown in FIG. 3B.

The process 942 shown in the flow diagram 903 of FIG. 9C may, for example, be identified with the process shown in FIG. 3C.

The process 944 shown in the flow diagram 903 of FIG. 9C may, for example, be identified with the process shown in FIG. 3D.

The process 946 shown in the flow diagram 903 of FIG. 9C may, for example, be identified with the process shown in FIG. 3E.

The process 948 shown in the flow diagram 903 of FIG. 9C may, for example, be identified with the process shown in FIG. 3F.

The process 950 shown in the flow diagram 903 of FIG. 9C may, for example, be identified with the processes shown in FIG. 3G and FIG. 3H.

The process 952 shown in the flow diagram 903 of FIG. 9C may, for example, be identified with the processes shown in FIG. 3I and FIG. 3J.

The process 954 shown in the flow diagram 903 of FIG. 9C may, for example, be identified with the process shown in FIG. 3K.

The process 956 shown in the flow diagram 903 of FIG. 9C may, for example, be identified with the patterning process described above.

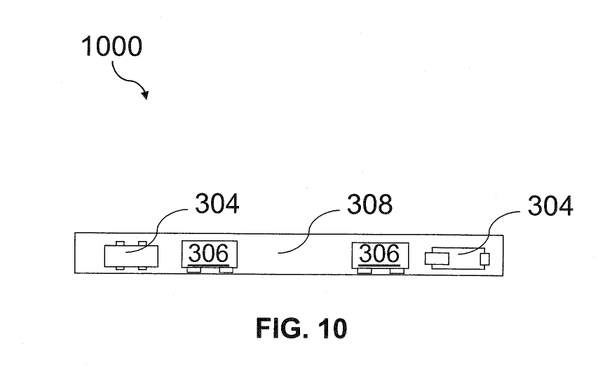

FIG. 10 shows a chip arrangement 1000.

Reference signs in FIG. 10 that are the same as in FIG. 3A to FIG. 3K denote the same or similar elements as in FIG. 3A to FIG. 3K. Thus, those elements will not be described in detail again here; reference is made to the description above.

The chip arrangement 1000 may, for example, be manufactured by means of the method 200 shown in FIG. 2.

The chip arrangement 1000 may include: a chip 306, a stabilizing structure 304 disposed next to the chip 306; and an encapsulating structure 308 encapsulating the chip 306 and the stabilizing structure 304.

According to various examples presented herein, a chip arrangement may be manufactured using large panel sizes and standard PCB materials and/or processes.

According to various examples presented herein, a chip may be bonded to a temporary thermal release tape of a carrier in a face-up and/or face-down arrangement. After bonding the chip to the temporary release tape, an insulating layer may be manufactured with standard PCB prepreg foils or prepregs and laminates. The insulating layer may be laminated over the chip bonded to the temporary release tape e.g. by means of a lamination process.

After laminating the insulating layer, the carrier and the release tape may be removed and the whole top or bottom side of the chip may be visible. After removal of the carrier and the release tape, an insulation layer may be laminated over of the chip, and microvias may be manufactured on both side of the panel to contact the chip to conductor layers that may be laminated on the chip. Plating and patterning may be performed either with direct metallization and subtractive process or normal pattern plating process (e.g. standard PCB processes). Because the process uses standard low cost, high volume PCB materials and manufacturing equipment, the manufacturing process may be low cost and can be performed on large panels.

The manufacturing process may allow exposure of the whole front side and/or or backside of the chip. Furthermore, a distance between a side of the chip and a conducting layer (e.g. copper surface) can be accurately fixed and manufactured without any voids. By replacing the center prepreg with PCB laminate (cured FR4), the warpage of the chip arrangement is smaller. Furthermore, dimensional stability of the chip arrangement may be improved (e.g. since cured laminate has remarkable smaller shrinkage than prepreg). This PCB laminate can also be patterned (conductors and vias) to improve the routing capability. A foil (e.g. copper foil) with thick carrier (e.g. aluminium or copper) carrier instead of a thin foil can be used to reduce warpage that may occur during lamination. In case a laminate is used for the stabilizing structure instead of prepregs, the manufacture of at least one thru-opening of the stabilizing structure may be easier and cheaper because instead of slow and expensive laser cutting, a routing or punching process can be used. This may also reduce a potential risk caused by the carbon that may be formed on the prepregs during laser cutting. The properties of this core layer can also be selected to suit for application (e.g. low CTE, ultralow CTE).

According to various examples presented herein, a method for manufacturing a chip arrangement may be provided. The method may include disposing a stabilizing structure and a chip including at least one contact next to each other and over a carrier; encapsulating the chip and the stabilizing structure by means of an encapsulating structure; and forming an electrically conductive connection to the at least one contact of the chip.

The stabilizing structure may include, or may consist of, at least one material selected from a group of materials, the group consisting of: a laminate material, a polymer material, a ceramic material, a metal, and a metal alloy.

The laminate material may include, or may consist of, a cured laminate material.

The stabilizing structure may include at least one electrically conductive layer.

The at least one electrically conductive layer may include a plurality of electrically conductive layers, and wherein the stabilizing structure may include at least one via extending through at least a portion of the stabilizing structure and electrically connecting a first electrically conductive layer of the plurality of electrically conductive layers to a second electrically conductive layer of the plurality of electrically conductive layers.

The stabilizing structure may include a bonding layer configured to attach the stabilizing structure to the carrier, wherein disposing the stabilizing structure and the chip may include the at least one contact next to each other and over the carrier may include attaching the stabilizing structure to the carrier by means of the bonding layer.

A thickness of the bonding layer of the stabilizing structure may be in the range from about 5 μm to about 150 μm.

The carrier may include at least one opening, wherein disposing the stabilizing structure and the chip including the at least one contact next to each other and over the carrier includes disposing the stabilizing structure over the at least one opening of the carrier, wherein a first portion of the bonding layer fills the at least one opening of the carrier, and wherein a second portion of the bonding layer is disposed over at least a part of a surface of the carrier outside the at least one opening.

Encapsulating the chip and the stabilizing structure may include a lamination process.

The encapsulating structure may include, or may consist of, at least one of a molding material, a prepreg material, a resin material, a laminate material, an electrically conductive material, and a thermally conductive material.

The laminate material may include, or may consist of, an uncured laminate material.

The stabilizing structure may include a thru-opening, wherein disposing the stabilizing structure and the chip including the at least one contact next to each other and over the carrier may include disposing the chip within the thru-opening of the stabilizing structure and over the carrier.

The thru-opening may be formed by means of at least one of a punching process, a routing process, a drilling, an etching process, and a laser structuring process.

The chip may include a first side facing the carrier and a second side opposite the first side, and wherein the at least one contact of the chip is disposed at the first side of the chip or the second side of the chip, or both.

Forming the electrically conductive connection to the at least one contact of the chip may include forming at least one opening in the encapsulating structure to expose the at least one contact of the chip.

Forming the electrically conductive connection to the at least one contact of the chip may include removing the carrier to expose the at least one contact of the chip.

Forming the electrically conductive connection to the at least one contact of the chip may include a plating process.

Forming the electrically conductive connection to the at least one contact of the chip may include: disposing a conductive layer over the at least one contact of the chip; forming the electrically conductive connection between the conductive layer and the at least one contact of the chip; and patterning the conductive layer.

Patterning the conductive layer may include an etching process.

Forming the electrically conductive connection between the conductive layer and the at least one contact of the chip may include a plating process.

Disposing the conductive layer over the at least one contact of the chip may include a lamination process.

Disposing the conductive layer over the at least one contact of the chip may include: disposing an insulating layer between the conductive layer and the at least one contact of the chip.

Forming the electrically conductive connection between the conductive layer and the at least one contact of the chip may include forming at least one opening in the conductive layer and the insulating layer to expose the at least one contact of the chip.

The carrier may include a plate and an adhesive layer disposed over the plate, wherein the adhesive layer faces the stabilizing structure and the chip, and wherein disposing the stabilizing structure and the chip including the at least one contact next to each other and over the carrier may include disposing the stabilizing structure and the chip over the adhesive layer of the carrier.

Forming the electrically conductive connection to the at least one contact of the chip may include removing the plate and the adhesive layer of the carrier to expose the at least one contact of the chip.

Removing the adhesive layer of the carrier may include at least one of dissolving the adhesive layer, peeling off the adhesive layer, and curing the adhesive layer.

The adhesive layer may include, or may be, a release tape.

The stabilizing structure may include at least one alignment mark, and wherein disposing the stabilizing structure and the chip including the at least one contact next to each other and over the carrier may include: disposing the stabilizing structure over the carrier; aligning the chip to the stabilizing structure by means of the at least one alignment mark; and disposing the chip next to the stabilizing structure and over the carrier.

According to various examples presented herein, a chip arrangement may be provided. The chip arrangement may include: a chip; a stabilizing structure disposed next to the chip; and an encapsulating structure encapsulating the chip and the stabilizing structure.

The stabilizing structure may include at least one material selected from a group of materials, the group consisting of: a laminate material, a polymer material, a ceramic material, a metal, and a metal alloy.

The laminate material may include a cured laminate material.

The stabilizing structure may include at least one electrically conductive layer.

The at least one electrically conductive layer may include a plurality of electrically conductive layers, and wherein the stabilizing structure may include at least one via extending through at least a part of the stabilizing structure and electrically connecting an electrically conductive layer of the plurality of electrically conductive layers to another electrically conductive layer of the plurality of electrically conductive layers.

The encapsulating structure may include, or may consist of, at least one of a molding material, a prepreg material, a resin material, and a laminate material.

The laminate material may include, or may consist of, an uncured laminate material.

Various examples and aspects described in the context of one of the chip arrangements or methods described herein may be analogously valid for the other chip arrangements or methods described herein.

While various aspects of this disclosure have been particularly shown and described with reference to these aspects of this disclosure, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A method for manufacturing a chip arrangement, the method comprising:
disposing a stabilizing structure and a chip comprising at least one contact next to each other and over a carrier,
wherein the stabilizing structure comprises a cured laminate material;
encapsulating the chip and the stabilizing structure by means of an encapsulating structure; and
forming an electrically conductive connection to the at least one contact of the chip.

2. The method of claim 1, wherein the stabilizing structure further comprises at least one material selected from a group of materials, the group consisting of: a laminate material, a polymer material, a ceramic material, a metal, and a metal alloy.

3. (canceled)

4. The method of claim 1, wherein the stabilizing structure comprises at least one electrically conductive layer.

5. The method of claim 4, wherein the at least one electrically conductive layer comprises a plurality of electrically conductive layers, and wherein the stabilizing structure comprises at least one via extending through at least a portion of the stabilizing structure and electrically connecting a first electrically conductive layer of the plurality of electrically conductive layers to a second electrically conductive layer of the plurality of electrically conductive layers.

6. The method of claim 1, wherein the stabilizing structure comprises a bonding layer configured to attach the stabilizing structure to the carrier, and wherein disposing the stabilizing structure and the chip comprising the at least one contact next to each other and over the carrier comprises attaching the stabilizing structure to the carrier by means of the bonding layer.

7. The method of claim 6, wherein the carrier comprises at least one opening, and wherein disposing the stabilizing structure and the chip comprising the at least one contact next to each other and over the carrier comprises disposing the stabilizing structure over the at least one opening of the carrier, wherein a first portion of the bonding layer fills the at least one opening of the carrier, and wherein a second portion of the bonding layer is disposed over at least a part of a surface of the carrier outside the at least one opening.

8. The method of claim 1, wherein encapsulating the chip and the stabilizing structure comprises a lamination process.

9. The method of claim 1, wherein the encapsulating structure comprises at least one of a molding material, a prepreg material, a resin material, a laminate material, an electrically conductive material, and a thermally conductive material.

10. The method of claim 1, wherein the stabilizing structure comprises a thru-opening, and wherein disposing the stabilizing structure and the chip comprising the at least one contact next to each other and over the carrier comprises disposing the chip within the thru-opening of the stabilizing structure and over the carrier.

11. The method of claim 1, wherein the chip comprises a first side facing the carrier and a second side opposite the first side, and wherein the at least one contact of the chip is disposed at the first side of the chip or the second side of the chip, or both.

12. The method of claim 1, wherein forming the electrically conductive connection to the at least one contact of the chip comprises forming at least one opening in the encapsulating structure to expose the at least one contact of the chip.

13. The method of claim 1, wherein forming the electrically conductive connection to the at least one contact of the chip comprises removing the carrier to expose the at least one contact of the chip.

14. The method of claim 1, wherein forming the electrically conductive connection to the at least one contact of the chip comprises a plating process.

15. The method of claim 1, wherein forming the electrically conductive connection to the at least one contact of the chip comprises:
disposing a conductive layer over the at least one contact of the chip;
forming the electrically conductive connection between the conductive layer and the at least one contact of the chip; and
patterning the conductive layer.

16. The method of claim 15, wherein forming the electrically conductive connection between the conductive layer and the at least one contact of the chip comprises a plating process.

17. The method of claim 15, wherein disposing the conductive layer over the at least one contact of the chip comprises:
disposing an insulating layer between the conductive layer and the at least one contact of the chip.

18. The method of claim 17, wherein forming the electrically conductive connection between the conductive layer and the at least one contact of the chip comprises forming at least one opening in the conductive layer and the insulating layer to expose the at least one contact of the chip.

19. The method of claim 1, wherein the carrier comprises a plate and an adhesive layer disposed over the plate, wherein the adhesive layer faces the stabilizing structure and the chip, and wherein disposing the stabilizing structure and the chip comprising the at least one contact next to each other and over the carrier comprises disposing the stabilizing structure and the chip over the adhesive layer of the carrier.

20. The method of claim 19, wherein forming the electrically conductive connection to the at least one contact of the chip comprises removing the plate and the adhesive layer of the carrier to expose the at least one contact of the chip.

21. A chip arrangement, comprising:
a chip;
a stabilizing structure disposed next to the chip,
wherein the stabilizing structure comprises a cured laminate material; and
an encapsulating structure encapsulating the chip and the stabilizing structure.

22. The chip arrangement of claim 21, wherein the stabilizing structure further comprises at least one material selected from a group of materials, the group consisting of: a laminate material, a polymer material, a ceramic material, a metal, and a metal alloy.

23. The chip arrangement of claim 21, wherein the stabilizing structure comprises at least one electrically conductive layer.
